(19) United States
(12) Patent Application Publication
(10) Pub. No.: US 2014/0014169 A1
(43) Pub. Date: Jan. 16, 2014

(54) NANOSTRING MATS, MULTI-JUNCTION DEVICES, AND METHODS FOR MAKING SAME

(71) Applicant: TRITON SYSTEMS, INC., Chelmsford, MA (US)

(72) Inventors: James A. RAND, Landenberg, PA (US); Scott MORRISON, Maynard, MA (US); John BLUM, Petersham, MA (US)

(21) Appl. No.: 13/942,430

(22) Filed: Jul. 15, 2013

Related U.S. Application Data
(60) Provisional application No. 61/671,401, filed on Jul. 13, 2012.
(60) Provisional application No. 61/752,746, filed on Jan. 15, 2013.

(51) Int. Cl. H01L 31/0352; H01L 31/18

(52) U.S. Cl. CPC H01L 31/035236; H01L 31/18; B82Y 99/00
USPC 136/255; 438/64; 257/9; 977/765; 977/890; 977/948

(57) ABSTRACT

Semiconductor nanostrings, mats containing semiconductor nanostrings, and devices and modules, such as, solar energy generating modules, including semiconductor nanostrings or mats containing semiconductor nanostrings are described herein. Methods for making multi-layer nanostrings and mats and other devices including multi-layer nanostrings are also described.

### CROSS-REFERENCE TO RELATED APPLICATIONS

This application claims priority to U.S. Provisional Application No. 61/671,401, entitled, “Silicon Nanostring Mat For Photovoltaic Applications” filed Jul. 13, 2012, and U.S. Provisional Application No. 61/752,746, entitled, “Nanostring Mats, Multi-Junction Devices, and Methods for Making Same” filed Jan. 15, 2013, which are incorporated herein by reference in their entirety.

### GOVERNMENT INTERESTS

Not Applicable

### PARTIES TO JOINT RESEARCH AGREEMENT

Not Applicable

### INCORPORATION BY REFERENCE OF MATERIAL SUBMITTED ON A COMPACT DISC

Not applicable

### BACKGROUND

Solar cells use photons to generate electricity. This process involves transferring the energy from a photon to separate charge carriers within a material. Conventional solar cells use semiconductors, such as silicon, having a band-gap in the range of energy of optical photons. Silicon, with a band-gap of 1.1 eV, is a desirable material for making solar cells. In general, high purity silicon is desirable for efficient carrier collection. However, high purity silicon, being weakly absorbing at some optical frequencies, may have poor absorption at some optical frequencies. Thickness in excess of 20 μm may, therefore, be required to improve the energy conversion efficiency of silicon solar cells. Coupled with high purity and larger material requirements, the cost of production of efficient silicon solar cells may be high. As such, there is a need for low-cost methods of fabricating silicon structures with higher energy conversion efficiency for solar cell applications.

FIG. 1A depicts an illustrative schematic of a planar p-n junction and a planar p-n junction photovoltaic cell, and FIG. 1B depicts an illustrative schematic of a radial p-n junction photovoltaic cell. As illustrated in FIG. 1A, conventional (planar) p-n junction 100 includes at least one region composited of an n-type semiconductor (n-type region, 121A) and an adjacent region containing a p-type semiconductor (p-type region, 122A). When the n and p-type semiconductors are joined, a non-conductive depletion zone 125A, named for the depletion of charge carriers in this region, is formed. When a p-n junction containing device 180A, 180B is contacted by high energy particles such as, for example, photons 140A, 140B, the photons may be absorbed in either the n-layer, the depletion zone, or the p-type layer, and an electron-hole pair is generated. In the case of absorption in the in the depletion zone 125A, excited electrons migrate towards the n-type region 121A, 121B (and holes to migrate toward the p-type region 122A, 122B) generating a potential difference. For absorption in the n-type or p-type regions, the minority carrier diffuses to the edge of the depletion zone, where it collects creating a charge separation. When an external circuit 175A, 175B is connected to the p-n junction, the electrons 101A from the n-type region 121A, 121B flow (direction of electron flow depicted by the arrow) into the metal contact (cathode) 120A, 120B through the external circuit 175A, 175B to the anode 130A, 130B where they recombine 150A with the holes 102A. If the electron-hole pair recombine within the depletion region 125A, no potential difference is achieved.

In a traditional wafer based photovoltaic cell (FIG. 1A), the n-type region 121A should be relatively thin so that photons can penetrate the n-type region 121A to reach the p-type region 122A. The p-type region 122A can be relatively thick to allow for absorption of as many photons as possible, so as to create a larger number of electron-hole pairs and allow for electron-hole separation before they can recombine 150A. In a radial p-n junction (as depicted in FIG. 1B), the p-type region 122B forms a core of a silicon wire, while the n-type region 121B forms the outer part or the shell. Large numbers of fibers may assist in absorption by increasing the probability of any reflected or transmitted photons being collected by interactions with other fibers (light trapping).

The wafer based photovoltaic cell suffers from the fact that is comprised of a single semiconductor material. The band gap of the material determines the corresponding narrow portion of the solar spectrum which will facilitate generation of an electron-hole pair. To overcome this disadvantage of a single material, multi junction solar cells, which combine several materials with differing band gaps have been developed. As illustrated in FIG. 2, the efficiency for multi junction solar cells increases as the number of junctions increases.

### BRIEF SUMMARY OF THE INVENTION

Embodiments of the invention are directed to a nanostring including at least one core nanostring having a length of greater than 20 μm and at least one semiconductor layer covering the at least one core. In some embodiments, the core nanostring may include crystalline silicon, and in certain embodiments, the crystalline silicon may be from about 75 wt. % to 100 wt. % of the core nanostring. In particular embodiments, the crystalline silicon core nanostring may further include a dopant material, and in various embodiments, the dopant material may be selected from the group consisting of, aluminum, boron, phosphorous, arsenic, gallium, antimony, indium, and combinations thereof. The core nanostring in such embodiments may include from about 0.001 wt. % to about 25 wt. % dopant material, and the dopant material may enhance the electrical conductivity of the core nanostring.

In other embodiments, the core nanostring may include a semiconductor material, and the semiconductor material may be any semiconductor material silicon, carbon, germanium, aluminum nitride, gallium nitride, indium gallium arsenide, aluminum gallium arsenide, cadmium selenide, cadmium sulfide, cadmium telluride, zinc oxide, zinc selenide, zinc sulfide, zinc telluride, cadmium zinc telluride, mercury cadmium telluride, mercury zinc telluride, mercury zinc selenide, aluminum antimonide, aluminum arsenide, aluminum nitride, aluminum phosphide, boron nitride, boron phosphide, boron arsenide, gallium antimonide, gallium arsenide, gallium nitride, gallium phosphide, indium antimonide, indium arsenide, indium nitride, indium phosphide, aluminum gallium arsenide, indium gallium arsenide, indium gallium phosphide, aluminum indium arsenide, aluminum indium antimonide, gallium arsenide nitride, gallium arsenide phosphide, aluminum gallium nitride, aluminum gallium phosphide, indium gallium nitride, indium arsenide antimonide, indium gallium antimonide, aluminum gallium indium phosphide, aluminum gallium arsenide phosphide, indium gallium arsenide phosphide, aluminum indium arsenide phosphide, aluminum gallium arsenide nitride, indium gallium arsenide nitride, indium aluminum arsenide nitride, gallium arsenide antimonide nitride, gallium indium nitride arsenide antimonide, gallium indium arsenide antimonide phosphide, and the like and combinations thereof. In certain embodiments, the core nanostring may include from about 75 wt. % to about 100 wt. % semiconductor material. In some embodiments, the core nanostring may include a dopant material such as, but not limited to, copper, aluminum, gold, boron, phosphorous, arsenic, indium, arsenic, gallium, boron, oxygen, and combinations thereof. The core nanostring may include from about 0.001 wt. % to about 25 wt. % dopant material, and the dopant material may enhance the electrical conductivity of the of the core nanostring.

In various embodiments, the core nanostring may have a length of up to about 10 meters, and in some embodiments, the nanostring may have a diameter of about 5 nm to about 2500 nm. In certain embodiments, the nanostring may include an outer layer one or more insulating, passivating, or anti-reflecting layer.

The semiconductor layer of embodiments may include a semiconductor material such as, but not limited to, silicon, carbon, germanium, aluminum nitride, gallium nitride, indium gallium arsenide, aluminum gallium arsenide, cadmium selenide, cadmium sulfide, cadmium telluride, zinc oxide, zinc selenide, zinc sulfide, zinc telluride, cadmium zinc telluride, mercury cadmium telluride, mercury zinc telluride, mercury zinc selenide, aluminum antimonide, aluminum arsenide, aluminum nitride, aluminum phosphide, boron nitride, boron phosphide, boron arsenide, gallium antimonide, gallium arsenide, gallium nitride, gallium phosphide, indium antimonide, indium arsenide, indium nitride, indium phosphide, aluminum gallium arsenide, indium gallium arsenide, indium gallium phosphide, aluminum indium arsenide, aluminum indium antimonide, gallium arsenide nitride, gallium arsenide phosphide, aluminum gallium nitride, aluminum gallium phosphide, indium gallium nitride, indium arsenide antimonide, indium gallium antimonide, aluminum gallium indium phosphide, aluminum gallium arsenide phosphide, indium gallium arsenide phosphide, aluminum indium arsenide phosphide, aluminum gallium arsenide nitride, indium gallium arsenide nitride, indium aluminum arsenide nitride, gallium arsenide antimonide nitride, gallium indium nitride arsenide antimonide, gallium indium arsenide antimonide phosphide, and combinations thereof. In some embodiments, the semiconductor material may be doped. In certain embodiments, the semiconductor layer may completely covers the core nanostring, and in other embodiments, the semiconductor layer partially covers the core nanostring.

In some embodiments, the nanostring core may include an n-type semiconductor material and the semiconductor layer may include a p-type semiconductor layer. In other embodiments, the semiconductor layer comprises a first inner layer and a second inner layer. In such embodiments, the first inner layer may include an n-type semiconductor material, the second inner layer may include a p-type semiconductor material, and the core nanostring may include a conductive material.

Other embodiments are directed to mats including an encapsulant material and at least one nanostring encapsulated within the encapsulant material, the nanostring having: at least one core nanostring having a length of greater than 20 μm and at least one semiconductor layer covering the at least one core. In some embodiments, the mat may further include a substrate made from a material such as, but not limited to, glass, quartz, silicon, silicon dioxide, carbon black, graphite, graphene, carbon nanotubes, metals, copper, gold, silver, aluminum, tin, alloys thereof, and combinations thereof. In certain embodiments, the mat may include an anode and a cathode. In particular embodiments, the at least one nanostring may include a plurality of interconnected nanostrings. In some embodiments, the plurality of nanostrings can be patterned, and in other embodiments, the plurality nanostrings may be randomly arranged. In certain embodiments, the at least one nanostring may include a plurality of collinearly arranged nano strings.

Particular embodiments are directed to a multi junction device including at least one nanostring layers each nanostring of the at least one nanostring layers having: at least one core nanostring having a length of greater than 20 μm; and at least one semiconductor layer covering the at least one core. In some embodiments, the multi junction device may be a photovoltaic cell, and in other embodiments, the multi junction device may include a photovoltaic cell.

Further embodiments are directed to methods for making a nanostring including the steps of: electrospinning a core nanostring and depositing one or more layers of a semiconductor material onto the core nanostring. In various embodiments, electrospinning may result in a plurality of interconnected nanostrings. In some embodiments, the method may further include encapsulating the nanostring in an encapsulant material, and in some embodiments, the method may include removing the substrate after encapsulating.

### DESCRIPTION OF DRAWINGS

For a fuller understanding of the nature and advantages of the present invention, reference should be made to the following detailed description taken in connection with the accompanying drawings, in which:

FIG. 1A shows a schematic of a planar p-n junction solar cell.

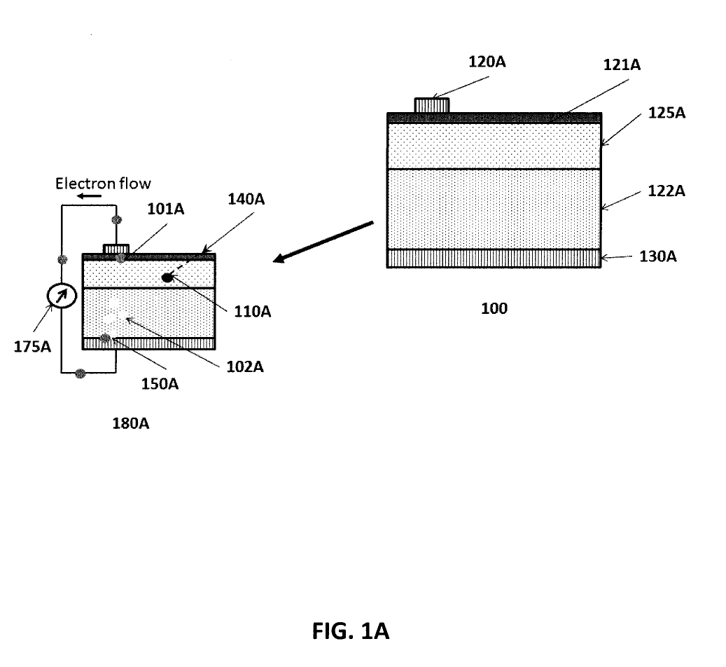

FIG. 1B shows a schematic of a radial p-n junction solar cell.

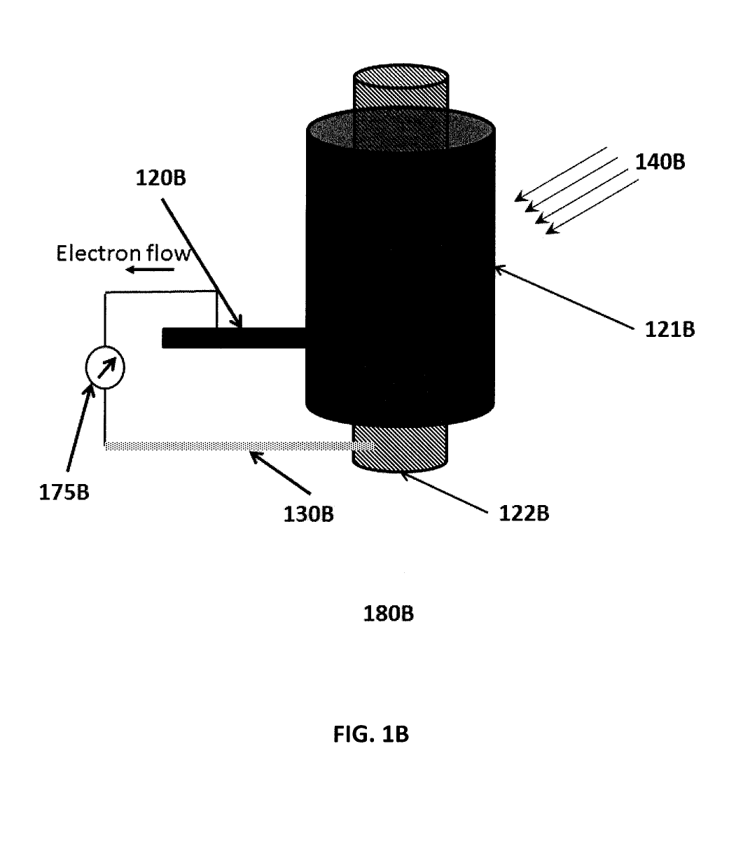

FIG. 2 is a graph showing the theoretical efficiencies and champion efficiencies of materials having various crystalline states as a function of the number of junctions in a solar cell.

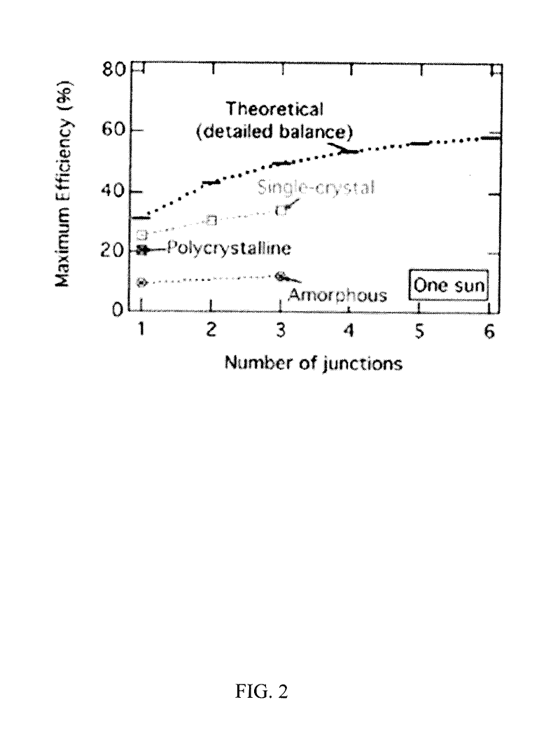

FIG. 3 shows a schematic illustrating the process for fabricating a multi-junction device by electrospinning nanostrings.

FIG. 4A. and FIG. 4b are illustrations of multi-layered nanostrings.

FIG. 5 is an illustration of a nanostring mat.

FIG. 6 is an illustration of a nanostring mat including an anode and a cathode.

FIG. 7 is an illustration of a monolithic photovoltaic cell having multiple semiconductor layers and a schematic of the cell.

FIG. 8 is an illustration of a monolithic device having multiple nanostring layers.

FIG. 9 is an illustration of a mechanically stacked device having multiple nanostring layers.

FIG. 10 is an illustration of a mechanically stacked device having multiple polymer embedded nanostring sheets.

FIG. 11 is a flow diagram of a method for making nanostrings.

FIG. 12 is a flow diagram of a method for fabricating a photovoltaic module.

FIG. 13 is a table showing the results of modeling of the spectrally weighted absorption of an idealized structure of densely packed nanostrings.

FIG. 14 shows absorption measurements of amorphous silicon nanostrings on a quartz substrate.

### DETAILED DESCRIPTION

Before the present compositions and methods are described, it is to be understood that they are not limited to the particular compositions, methodologies, or protocols described, as these may vary. This disclosure is not limited to the particular systems, devices and methods described, as these may vary. It is also to be understood that the terminology used in the description is for the purpose of describing the particular versions or embodiments only, and is not intended to limit their scope which will be limited only by the appended claims.

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. Nothing in this disclosure is to be construed as an admission that the embodiments described in this disclosure are not entitled to antedate such disclosure by virtue of prior invention. Although any methods and materials similar or equivalent to those described herein can be used in the practice or testing of embodiments disclosed, the preferred methods, devices, and materials are now described.

“Optional” or “optionally” means that the subsequently described event or circumstance may or may not occur, and that the description includes instances where the event occurs and instances where it does not. “Substantially no” means that the subsequently described event may occur at most about less than 10% of the time or the subsequently described component may be at most about less than 10% of the total composition, in some embodiments, and in others, at most about less than 5%, and in still others at most about less than 1%.

The term “composed” as used herein means that the materials identified are included in the described device or composition. The material identified may be the sole component. For example, a nanostring that is “composed of GaAs may be 100% GaAs and may include no other materials. In other cases, the material identified may be a constituent part of the device or composition and may be combined with another material and one or more contaminants that may or may not provide some benefit. For example, a nanostring that is “composed of 100% GaAs may include an amount of contaminant carbon, and in some cases, the contaminant carbon may improve the performance of the nanostring.

As used herein, the term “p-type” refers to doped semiconductor, wherein the majority of charge carriers are holes. When the semiconductor is a group IV element, the dopants that may be used for obtaining p-type semiconductor may include, for example, aluminum, boron, gallium, indium, and/or the like.

As used herein, the term “n-type” refers to doped semiconductor, wherein the majority of charge carriers are electrons. When the semiconductor is a group IV element, dopants that may be used for obtaining an n-type semiconductor may include, for example, nitrogen, phosphorus, arsenic, antimony, and/or the like.

As used herein, the term “metallic” refers to materials having electrical conductivity greater than about 500 Siemen/centimeter (S/cm), greater than about 750 S/cm, greater than about 800 S/cm, greater than about 900 S/cm, or greater than about 1,000 (10³) S/cm. Such materials may include metals such as, for example, aluminum, silver, gold, copper, platinum, iron, tungsten, tin, titanium, nickel, and/or the like. Alloys such as, for example, carbon steel, tin/lead, tin-copper-silver, bismuth-tin-lead, indium-lead, indium-tin-lead-cadmium, tin-lead-silver, lead-indium-silver, tin-silver, tin-copper, tin-zinc, tin-aluminum, indium-gold, Nitinol, a combination thereof, and/or the like are also considered metallic. Likewise, doped metal oxides such as, for example, indium doped tin oxide, fluorine doped tin oxide, doped zinc oxide, and/or the like are considered metallic. Additionally, undoped or doped conducting polymers such as, for example, derivatives of polythiophenes, polyaniline, polypyrrole, polyacetylene, combinations thereof, and/or the like may be considered metallic.

The term “layer” as used herein is meant to refer to a thickness of nanostrings encapsulated within the encapsulating material where each of the nanostrings have substantially the same composition in each of the core, one or more inner layers, and outer layer.

Electrospinning is carried out by preparing a liquid precursor material, most commonly a polymer in solution, and pushing the liquid precursor through a tip that is positioned above a substrate. The tip and substrate have a large potential (kV range) set between them, and the electrostatic attraction of the liquid to the (grounded) substrate causes a very fine stream of liquid to be pulled off of the tip. The solvent is evaporated during travel to the substrate resulting in a solid thread that is deposited on the substrate. Using this process, a type of nonwoven ‘mat’ of fibers can be formed.

Embodiments of the invention are generally directed to semiconductor nanostrings, semiconductor nanostring containing mats, and assemblies and devices including semiconductor nanostrings and semiconductor nanostring containing mats. The semiconductor nanostrings, semiconductor nanostring containing mats, and assemblies and devices including semiconductor nanostrings and semiconductor nanostring containing mats of various embodiments may have a number of utilities, and embodiments are not limited to any particular assemblies or devices. However, some embodiments are directed to semiconductor nanostring mats that can be used in photovoltaic (PV) modules that can be incorporated into, for example, solar cells, and in certain embodiments, the semiconductor nanostrings and semiconductor nonstring mats may be incorporated into multi junction photovoltaic devices. Further embodiments are directed to methods for making semiconductor nanostrings and semiconductor nanostring mats, as well as other assemblies and devices such as PV modules incorporating the semiconductor nanostrings and semiconductor nanostring mats. Further embodiments are directed to solar cells and other devices incorporating the PV modules. The assemblies and devices of embodiments may have exhibit low semiconductor utilization, which is defined herein as grams of semiconductor material divided by watts of power generated under standard solar cell test conditions, for example, less than about 0.05 g/W, less than about 0.1 g/W, less than about 0.2 g/W, less than about 0.5 g/W, less than about 1.0 g/W, or from about 0.05 g/W to about 1.0 g/W, while maintaining high efficiency, for example, greater than 12%, greater than 17%, greater than 20%, greater than 25%, greater than 30%, or from about 15% to about 30%.

The semiconductor nanostrings of various embodiments may at least include a core and a semiconductor layer covering or partial covering the core. In other embodiments, the semiconductor nanostrings may include a core, at least one first semiconductor layer, and at least one second semiconductor layer in which each of the first semiconductor layer and the second semiconductor layers, independently, cover or partially cover the preceding adjacent layer. In further embodiments, the semiconductor nanostrings having at least one first semiconductor layer or at least one first semiconductor layer and at least one second semiconductor layer may further include one or more of a passivation layer, and antireflection layer, and in certain embodiments, the passivation layer and the antireflection layer can be encompassed in a single layer. Thus, embodiments include nanostrings including a core, first semiconductor layer, second semiconductor layer, and passivation/antireflection layer.

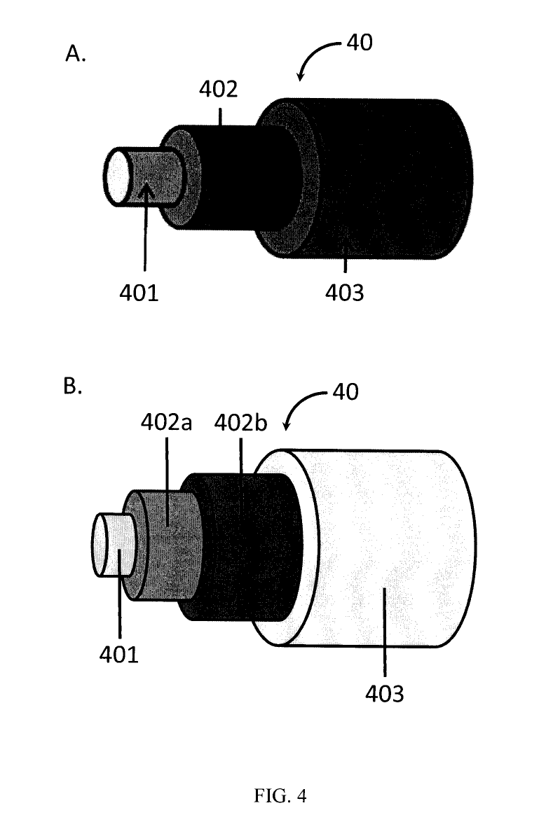

As illustrated in FIG. 4, the nanostrings 40 of various embodiments may include at least a core 401, an inner layer 402, and an outer layer 403, and in some embodiments, at least the core 401 and inner layer 402 may be composed of semiconductor materials. The semiconductor materials used in the core 401 and inner layer 402 of such embodiments may be any semiconductor material known in the art including, but not limited to, doped semiconductor materials, undoped semiconductor materials, micro-crystalline, polycrystalline, amorphous, or single crystalline semiconductor. In such embodiments, the core may be composed of any material capable of providing a surface on which semiconductor materials can be crystallized, and in some embodiments, the core may be composed of a semiconductor material such as a p-type semiconductor. In certain embodiments, the core 401 may be composed of a p-type semiconductor material and the inner layer 402 may be composed of an n-type semiconductor material.

In other embodiments, the core 401 may be composed of a conductive material that can be coated with a first inner layer 402a of a first semiconductor material and a second inner layer 402b of a second semiconductor material. The core 401 of such embodiments may be composed of any conductive material and may allow for enhanced conductivity for long strings. In addition, the radial configured nanostrings with a conductive core may lower the minority carrier diffusion length requirement of the semiconductor. For example, in various embodiments, the diffusion length of the minority carrier may be less than about 100 μm, less than about 50 μm, less than about 20 μm, less than about 5 μm, or less than about 1 μm, which may allow for great tolerance to material quality requirements. Building the string radially from the core may further allow for equivalent of a back surface field to be built into the device to increase collection efficiency.

In embodiments including a core 401 composed of a conductive material, the first inner layer 402a may be composed of a p-type semiconductor material and the second inner layer 402b may be composed of an n-type semiconductor material. In further embodiments, third, fourth, fifth, sixth, or any number of additional inner layers may coat or partially coat the core 401. While FIG. 4 shows successive layers 402, 403 completely encircling the core 401, in some embodiments, the inner layer 402 and/or the outer layer 403 may only cover a portion of the core 401. In various embodiments, the outer 403 layer may have a thickness of about 2 nm to about 10 nm.

The core of various embodiments typically consist of continuous strings of material. These strings are typically flexible and can be bent, twisted, coiled, looped, woven, knotted, and the like without breaking Thus, the nanostring layers of various may be made into nearly any shape. For example, in some embodiments, the nanostrings incorporated into the assemblies and devices may have a length of greater than about 20 μm, greater than about 30 μm, greater than about 50 μm, greater than about 60 μm, greater than about 65 μm, greater than about 70 μm, greater than about 75 μm, greater than about 80 μm, greater than about 90 μm, greater than about 100 μm, greater than about 150 μm, greater than about 200 μm, greater than about 300 μm, or greater than about 500 μm. Thus, the nanostrings of some embodiments may have a length of about 50 μm to about 500 μm, 100 μm about 100 mm. 500 μm to about 500 mm, 1 mm to about 100 cm, 100 mm to about 1 meter, or any individual length or range encompassed by these example ranges. In still other embodiments, the core nanostring may have a length of greater than about 1 meter or up to about 10 meters, or any individual length or range encompassed by these example ranges. The length of the core and the multi-layered nanostrings having one or more semiconductor layers covering or partially covering the core may allow for enhanced conductivity for long strings, which can result in nanostring mats, modules, and devices that more efficiently, collect, trap, and move electrical charges in, for example, photovoltaic cells.

As discussed above, the core 401 can include a conductive or semiconductor material. In particular embodiments, the core 401 may include a mixture of crystalline silicon and a conductive material such as, for example, silver, copper, aluminum, gold, boron, phosphorous, arsenic, gallium, antimony, indium, and the like and combinations thereof, and in certain embodiments, the core 401 can be composed of crystalline silicon and aluminum. The crystalline silicon can be derived from any source, and in certain embodiments, the crystalline silicon in the core may be derived from a liquid silicon precursor such as, for example, Si₆H₁₂In other embodiments, the core 401 can be composed of crystalline silicon and a semiconductor material. Any of the semiconductor materials described below including group IV semiconductor materials, group II-VI semiconductor materials, groups III-V semiconductor materials, and combinations thereof can be incorporated into the core 401, and in certain embodiments, the semiconductor materials may be, for example, germanium, gallium arsenide, gallium nitride, gallium phosphide, zinc oxide, and the like or combinations thereof. In further embodiments, the core 401 can include additives to increase their conductivity such as, conductive materials and semiconductive materials described above, metallic materials and metallic compounds, for example, those described above, and combinations thereof.

In embodiments, the core 401 may include crystalline silicon from about 75 wt. % to 100 wt. %, about 80 wt. % to about 99 wt. %, about 85 wt. % to about 98 wt. %, or any value or range between these values. The core 401 of such silicon nanostrings may include one or more conductor material, semiconductor material, and combinations thereof in addition to the crystalline silicon that can each be from about 0.01 wt. % to about 25 wt. %, 0.5 wt. % to about 25 wt. %, about 1 wt. % to about 20 wt. %, about 2 wt. % to about 15 wt. % or about 5 wt. % to about 10 wt. % of the total composition.

In embodiments, the core 401 may be composed entirely of the semiconductor material. For example, the core 401 may include about 100 wt. % semiconductor material or at least 99.9 wt. %, 99.8 wt. %, 99.5 wt. %, 99.0 wt. % or 98.0 wt. % semiconductor material or a range or values between these examples of concentrations. In other embodiments, the semiconductor material may make up about 75 wt. % to 100 wt. %, about 80 wt. % to about 99 wt. %, about 85 wt. % to about 98 wt. %, or any value or range between these values, and the core 401 may further include one or more conductor material, semiconductor material, and combinations thereof in addition to the semiconductor material that can each be from about 0.5 wt. % to about 25 wt. %, about 1 wt. % to about 20 wt. %, about 2 wt. % to about 15 wt. % or about 5 wt. % to about 10 wt. % of the total composition. The at least one inner layer 402 can be composed of a conductive or semiconductive material, and in certain embodiments, the inner layer 402 may include crystalline silicon derived from a liquid silicon precursor such as, for example, Si₆H₁₂. The conductive material can be the same or different from the conductive material in the core nanostring. For example, in some embodiments, the core 401 may include dopants including, but not limited to, silver, copper, aluminum, gold, boron, phosphorous, arsenic, indium, arsenic, gallium, boron, oxygen, and the like and combinations thereof and the inner layer 402 may include silver, copper, aluminum, gold, boron, phosphorous, arsenic, indium, arsenic, gallium, boron, oxygen, and the like or combinations thereof. In other embodiments, the core 401 may be a conductive material such as, for example, silver, copper, aluminum, gold, and the like or combinations thereof, and the inner layer 402 may be a semiconductor material. In still other embodiments, the core 401 may be a semiconductor material such as, for example, germanium, gallium arsenide, gallium nitride, gallium phosphide, zinc oxide and the inner layer 402 may be a semiconductor material. In particular embodiments, the core 401 may include a first semiconductor material, such as, for example, an n-type semiconductor material and the inner layer 402 may include a second semiconductor material such as, for example, a p-type semiconductor material.

In some embodiments, the nanostrings may include more than one inner layer 402. Additional inner layers may include a conductor or semiconductor material that is the same or different from the conductive or semiconductor materials in adjoining inner layers or the core. For example, in some embodiments, the nanostrings may include a core 401 of a conductive material, a first inner layer 402a of a first semiconductor material, such as an n-type semiconductor material, and a second inner layer 402b of a second semiconductor material, such as a p-type semiconductor material. In other embodiments, the nanostrings may include a core 401 of a first semiconductor material such as an n-type semiconductor material, a first inner layer 402a of a second semiconductor material such as a p-type semiconductor material, and a second inner layer 402b of a third semiconductor material such as a p-type semiconductor material that can be the same or different from the second semiconductor material. In still other embodiments, the second semiconductor material in the first inner layer 402a in such nanostrings may be an n-type semiconductor that is the same or different from the semiconductor material of the core 401, and in further embodiments, the third semiconductor material in the second inner layer 402b may be an n-type semiconductor material that is the same or different from the semiconductor material of the core 401.

A variety of semiconductor materials can be used in the at least one inner layers 402 such as the first and second inner layers described above, including group IV semiconductor materials, group II-VI semiconductor materials, groups III-V semiconductor materials, and combinations thereof. Group IV materials can include silicon, carbon (e.g. diamond), germanium, and combinations thereof such as silicon carbide and silicon germanium. In certain embodiments, the inner layer 402 may include a crystalline semiconductor material and crystalline silicon, for example, the inner layer 402 may include at least one of silicon, carbon, germanium, aluminum nitride, gallium nitride, indium gallium arsenide, aluminum gallium arsenide, and combinations thereof. Group II-VI materials that can be used in the inner layer 402 can include, for example, cadmium selenide, cadmium sulfide, cadmium telluride, zinc oxide, zinc selenide, zinc sulfide, zinc telluride, cadmium zinc telluride, mercury cadmium telluride, mercury zinc telluride, mercury zinc selenide, and combinations thereof. Group III-V materials that can be used in the inner layer 402 can include aluminum antimonide, aluminum arsenide, aluminum nitride, aluminum phosphide, boron nitride, boron phosphide, boron arsenide, gallium antimonide, gallium arsenide, gallium nitride, gallium phosphide, indium antimonide, indium arsenide, indium nitride, indium phosphide, aluminum gallium arsenide, indium gallium arsenide, indium gallium phosphide, aluminum indium arsenide, aluminum indium antimonide, gallium arsenide nitride, gallium arsenide phosphide, aluminum gallium nitride, aluminum gallium phosphide, indium gallium nitride, indium arsenide antimonide, indium gallium antimonide, aluminum gallium indium phosphide, aluminum gallium arsenide phosphide, indium gallium arsenide phosphide, aluminum indium arsenide phosphide, aluminum gallium arsenide nitride, indium gallium arsenide nitride, indium aluminum arsenide nitride, gallium arsenide antimonide nitride, gallium indium nitride arsenide antimonide, gallium indium arsenide antimonide phosphide, and combinations thereof.

Any of the semiconductor material that are doped with or could be doped with, for example, aluminum, boron, gallium, indium, and the like and combinations thereof are considered p-type semiconductor materials because in these materials the majority of charge carriers are holes. Any semiconductor materials that are doped with or could be doped with, for example, nitrogen, phosphorus, arsenic, antimony, and the like or combinations thereof, are considered n-type semiconductor materials because in these materials, the majority of charge carriers are electrons.

Each inner layer 402 may be composed entirely of a single conductive or semiconductor material such as, the semiconductor materials described above and crystalline silicon. Thus, in some embodiments, each inner layer 402 may include about 100 wt. % semiconductor material or at least 99.9 wt. %, 99.8 wt. %, 99.5 wt. %, 99.0 wt. % or 98.0 wt. % semiconductor material or a range or values between these examples of concentrations. In other embodiments, the conductor or semiconductor material in the inner layer 402 may make up about 75 wt. % to 100 wt. %, about 80 wt. % to about 99 wt. %, about 85 wt. % to about 98 wt. %, or any value or range between these values, and each inner layer 402 may further include one or more conductor material, semiconductor material, and combinations thereof in addition to the semiconductor material that can each be from about 0.5 wt. % to about 50 wt. %, about 1 wt. % to about 30 wt. %, about 2 wt. % to about 25 wt. % or about 5 wt. % to about 10 wt. % of the total composition or any value or range within these ranges. In other embodiments, the each inner layer may include from about 25 wt. % to about 50 wt. % semiconductor material.

The outer layer 403 may be absent or the outer layer may be an insulator or passivating layer. In such embodiments, the outer layer 403 may be composed of a material such as, for example, silicon dioxide, silicon nitride, and the like, and combinations thereof, that coats the outer surface and chemically stabilizes the nanostring 40, trap excited electrons within the core 401 and inner layer 402, create an anti-reflective coating to improve the photon trapping efficiency, or combinations thereof. In some embodiments, the outer layer 403 may passivate the surface of the semiconductor material in the adjoining layer improving device performance creating a passivation layer.

The outer layer 403 when used to create a passivation layer may be of any material capable of passivating defects on the surface of the semiconductor material layer to which it is applied. In particular, the material may be a material capable of filling unsatisfied bonds on the surface of a semiconductor material or curing other defects on the surface of the material. The type of material used in the outer layer 403 passivation layer is not limited and can include, for example, silicon dioxide, silicon nitride, and the like and combinations thereof. In various embodiments, the outer layer 403 passivation layer may have a thickness of about 2 nm to about 200 nm, about 10 nm to about 150 nm, about 20 nm to about 100 nm, about 30 nm to about 75 nm, and any thickness within these exemplary ranges. In certain embodiments, the outer layer 403 may have a thickness of about 2 nm to about 10 nm. The passivation layer may chemically stabilize the nanostring and in some cases, create an anti-reflective coating so as to improve the photon trapping efficiency of the nanostrings. In certain exemplary embodiments, the passivation layer/antireflection coating may be composed of silicon nitride (Si₃N₄), silicon dioxide (SiO₂), titanium dioxide (TiO₂), and the like having a thickness of about 100 nm.

The nanostrings 40 of various embodiments may have a diameter of about 5 nanometer (nm) to about 2500 nm. Exemplary diameters of nanostrings include 5 nm, 10 nm, 20 nm, 50 nm, 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1000 nm, 1100 nm, 1200 nm, 1300 nm, 1400 nm, 1500 nm, 1600 nm, 1700 nm, 1800 nm, 1900 nm, 2000 nm, 2100 nm, 2200 nm, 2300 nm, 2400 nm, 2500 nm, or any value between any two of these values. Variation is to be expected in the diameter of individual nanostrings from any fabrication process and the values mentioned herein are to be considered as average values. In some embodiments, the core 401 may have a diameter of about 1%, about 5%, about 10%, about 15%, about 20%, about 25%, about 30%, about 35%, about 40%, about 45%, about 50%, about 55%, about 60%, about 65%, about 70%, about 75%, about 80%, about 85%, about 90%, about 95%, about 99%, or any value between any two of these values, of the diameter of the nanostring.

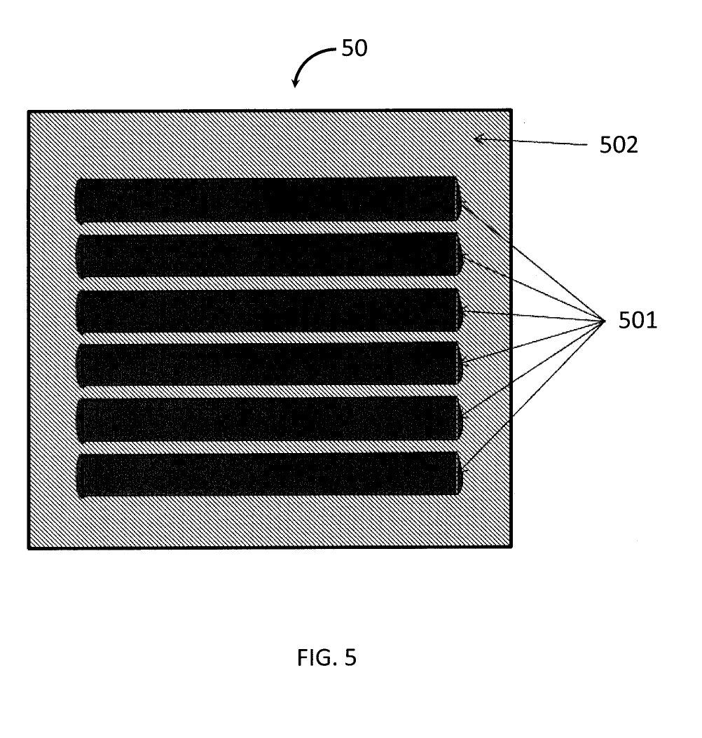

In some embodiments, as illustrated in FIG. 5, semiconductor nanostrings 501, such as those described above, may be disposed within or encapsulated by and encapsulating material 502. The encapsulating material 502 may vary among embodiments and within the various devices, and may typically be a transparent material. Examples of transparent encapsulating materials include, but are not limited to silicone, silicon oxide, silicon nitride, silicon oxynitride, silicon carbide, hafnium oxide, and aluminum oxide, photoresist, benzocyclobutene, cycloalkenes, polyimides, polyamides, polyesters, polyalcohols, polyethylene oxides, polyphenylenes, resins, polyethers, polyketide, and combinations thereof. In certain embodiments, the encapsulating material 502 may be a transparent polymer such as, for example, plexiglass, polyacetates (e.g., polyethylvinylacetate, ethyl vinyl acetate, polyethylenevinylacetate (EVA), polyvinylacetate), polyacrylates (e.g., polymethylmethacrylate (PMMA)), polycarbonates, olefin (e.g., polypropylene) and cyclic olefin polymers, styrenic polymers (e.g., polystyrene), polyurethanes, polyesters, polyethersulfone, polyimides, fluorinated polymers (e.g., polytetrafluoroethylene ((CH₂CF₂)ₙ) or (CHF)ₙ, polyvinylfluoride), sol-gel polymers (e.g., silica or other oxides), or inorganic-organic hybrid polymer.

Each nanostring 501 can have a length of up to about 10 cm, or from about 0.01 μm to about 10 cm, from about 0.5 μm to about 5 cm, about 1 μm to about 1000 μm, about 10 μm to about 500 μm, or any independent measurement or range there between. The nanostrings 501 may be composed of any of the materials and may have any of the configurations described above. In certain embodiments, the nanostrings 501 may include crystalline silicon (c-Si) derived from the liquid silicon such as Si₆H₁₂, and in some embodiments, the nanostrings may include crystalline silicon and one or more conductive materials, semiconductor materials, or combinations thereof in addition to the crystalline silicon. For example, in particular embodiments, the nanostrings 501 may include a mixture of crystalline silicon and a conductive material such as, for example, silver, copper, aluminum, gold, boron, phosphorous, arsenic, indium, arsenic, gallium, boron, oxygen, and the like or combinations thereof, and in certain embodiments, the nanostrings can be composed of crystalline silicon and aluminum. In other embodiments, the nanostrings can be composed of crystalline silicon and a semiconductor material such as, for example, germanium, gallium arsenide, gallium nitride, gallium phosphide, zinc oxide, and the like or combinations thereof

In other embodiments, the nanostrings 501 may be entirely or nearly entirely composed of a conductive or semiconductive material. For example, in some embodiments, the nanostrings 501 may be composed of a semiconductor material, cadmium selenide, cadmium sulfide, cadmium telluride, zinc oxide, zinc selenide, zinc sulfide, zinc telluride, cadmium zinc telluride, mercury cadmium telluride, mercury zinc telluride, mercury zinc selenide, aluminum antimonide, aluminum arsenide, aluminum nitride, aluminum phosphide, boron nitride, boron phosphide, boron arsenide, germanium, gallium antimonide, gallium arsenide, gallium nitride, gallium phosphide, indium antimonide, indium arsenide, indium nitride, indium phosphide, aluminum gallium arsenide, indium gallium arsenide, indium gallium phosphide, aluminum indium arsenide, aluminum indium antimonide, gallium arsenide nitride, gallium arsenide phosphide, aluminum gallium nitride, aluminum gallium phosphide, indium gallium nitride, indium arsenide antimonide, indium gallium antimonide, aluminum gallium indium phosphide, aluminum gallium arsenide phosphide, indium gallium arsenide phosphide, aluminum indium arsenide phosphide, aluminum gallium arsenide nitride, indium gallium arsenide nitride, indium aluminum arsenide nitride, gallium arsenide antimonide nitride, gallium indium nitride arsenide antimonide, gallium indium arsenide antimonide phosphide, and the like and combinations thereof. In other embodiments, the nanostrings may be composed of, for example, germanium, gallium arsenide, gallium nitride, gallium phosphide, zinc oxide, and the like or combinations thereof.

Mats 50 of the nanostrings 501described above can be encapsulated in an encapsulating material 502 as illustrated in FIG. 5. FIG. 5 shows an example of a mat of some embodiments of the invention that includes an encapsulating material 502 having an upper and lower surface with nanostrings 501 disposed within and encapsulated by the encapsulating material 502.

In other embodiments, nanostrings can be deposited on a surface of the substrate, and in still other embodiments, nanostrings can be deposited on both an upper and a lower surface of the substrate. In such embodiments, the nanostrings may be encapsulated by an encapsulating material, such as those encapsulating materials described above, and the encapsulating material may be deposited directly on the surface, or surfaces, of the substrate holding the nanostrings. In some embodiments, at least one surface of the substrate 502 may be coated or partially coated with nanostrings 501. For example, in some embodiments, about 0.1% to 99.9%, about 1% to about 99%, about 5% to about 98% of at least one surface of the substrate 502 may be covered by nanostrings 501, and in other embodiments, about 80% to about 100%, about 85% to about 98%, or about 90% to about 98% of at least one surface of the substrate may be covered by nanostrings.

The substrate may be, for example, glass, quartz, silicon, silicon dioxide, and the like, and combinations thereof, and in some embodiments, the substrate may be in the form of, for example, a foil, a wire-grid, a roll, a mesh, a web, a wafer, and/or the like. Examples of metals that may be used as substrates include, but are not limited to, copper, gold, silver, aluminum, tin, alloys thereof, and the like and combinations thereof. In some embodiments, the carbon matte may be composed of, for example, carbon black, graphite, graphene, carbon nanotubes, and the like and combinations thereof. In certain embodiments, a rolling mandrel may be made from a conducting tape of, for example, a metal or a carbon matte.

In some embodiments, the substrate may make up a lower junction of a device, and in such embodiments, the substrate may be composed of a conductive material such as, for example, a metal foil, wire mesh, quartz, and the like. In other embodiments, the substrate may be removed after the mat has been formed. For example, nanostrings can be deposited onto a substrate during electrospinning, the nanostrings can be processed by, for example, thermal or chemical processing, an encapsulating material that encapsulates the nanostrings may be applied to the nanostrings, and the nanostrings can be removed from the substrate leaving a nanostring mat, such as the mat 50 illustrated in FIG. 5. In embodiments, in which the substrate is removed, the substrate may be referred to as a “carrier.”

In the various embodiments described above, each of the nanostrings 501 can have the same composition, or in some embodiments, some of the nanostrings 501 may be composed of different materials. For example, crystalline silicon nanostrings and nanostrings including a conductive dopant or another semiconductor material can be simultaneously deposited on a substrate to produce a mat having nanostrings composed of a variety of materials in a single nanostring layer. The nanostrings 501 in the mats 50 of various embodiments are, generally, interconnected such that the nanostrings 501 contact at least one other nanostring, and typically, two or more nanostrings. Each junction between individual nanostrings allows for electrical current to be transferred, electrically connecting the nanostrings 501, and allowing electrical currents to travel in any direction on the mat 50 and over the entire surface of the mat 50.

In some embodiments, the nanostrings 501 may be randomly arranged within the encapsulating material 502. In some embodiments, the nanostrings 501 may be disposed within the encapsulating material 502 in a single layer. In other embodiments, the nanostrings 501 may be disposed in multiple layers within the encapsulating material 502 to form a mat. The layers of the nanostrings 501 may be randomly aligned (to form a randomly aligned mat), and in certain embodiments, the nanostrings may be patterned. For example, layers of nanostrings 501 may be orthogonal to each other, and in other embodiments, layers of nanostrings 501 may be aligned at specific angles to each other (to form a patterned mat). In some embodiments, the nanostrings 501 form an array in a direction orthogonal to the plane of the encapsulating material 502.

The mats 50 of various embodiments as described above including an encapsulating material 502 with nanostrings 501 disposed within the encapsulating material 502 can be integrated into devices individually. In such embodiments, the mat may include a single layer of nanostrings in which each nanostring has the same composition for each of the core, one or more inner layers, and outer layer as illustrated in FIG. 4. The layer of nanostrings may provide a coating that covers substantially all of a surface of the substrate and may include nanostrings or portions of nanostrings that are layered on top of one another. For example, in embodiments in which the nanostrings are randomly arranged within the encapsulating material portions of the layer of nanostrings may include a single nanostring and other portions of the layer may include two or more nanostrings or parts of various nanostrings deposited on top of one another. The thickness of a layer can vary among embodiments and within various portions of a layer. In some embodiments, a layer may have a thickness of from about 0.01 μm to about 100 μm, and in other embodiments, a layer may have a thickness of from about 0.1 μm to about 80 μm, about 0.75 μm to about 75 μm, about 1 μm to about 60 μm, about 5 μm to about 50 μm, or any value or range between these examples.

In various embodiments, the nanostrings of the mat may contact one another at one or more points this provides a finite, controllable, number of contact points between nanostrings. In some embodiments, thickening or recrystallization of the nanostrings may cause the contact points between nanostrings to be bound together physically, thereby introducing points of electrical contact. Thus, the nanostring mats of some embodiments can include electrical contact points between individual nanostrings. In some embodiments, these electrical contact points may be between neighboring nanostrings, and in other embodiments, the electrical contact points may span several nanostrings in close proximity with one another. For example, one or more nanostrings may simultaneously contact two or more nanostrings or a plurality of nanostrings in the nanostring mats of embodiments.

This redundancy of contact points may allow the device to act as a uniform material, where contact of the p-type material and n-type material can be achieved with only a few localize contact points and without the need to specifically contact each individual nanostring. The number of electrical contact points may be optimized by providing sufficient contact points to, for example, allow optimal light trapping, without leaving electrically isolated portions of the device or creating high resistance paths within portions of the device. Too few electrical contacts risk leaving areas of the mat electrically isolated, i.e., portions of the mat is not in electrical contact with the larger mat, or effectively isolated by high resistance paths. Too many would be wasteful and could interfere with, for example, light trapping.

In other embodiments, the mats can have multiple layers of nanostrings and each layer of nanostrings can be composed of a different combination of conductor materials or semiconductor materials. For example, a multi-layer mat may contain a first nanostring layer composed of nanostrings having a core of a first semiconductor material, an inner layer of a second semiconductor material, and an outer layer of an insulating material, and a second nanostring layer composed of nanostrings having a core of a third semiconductor material, a inner layer of a fourth semiconductor material, and an outer layer of an insulating material.

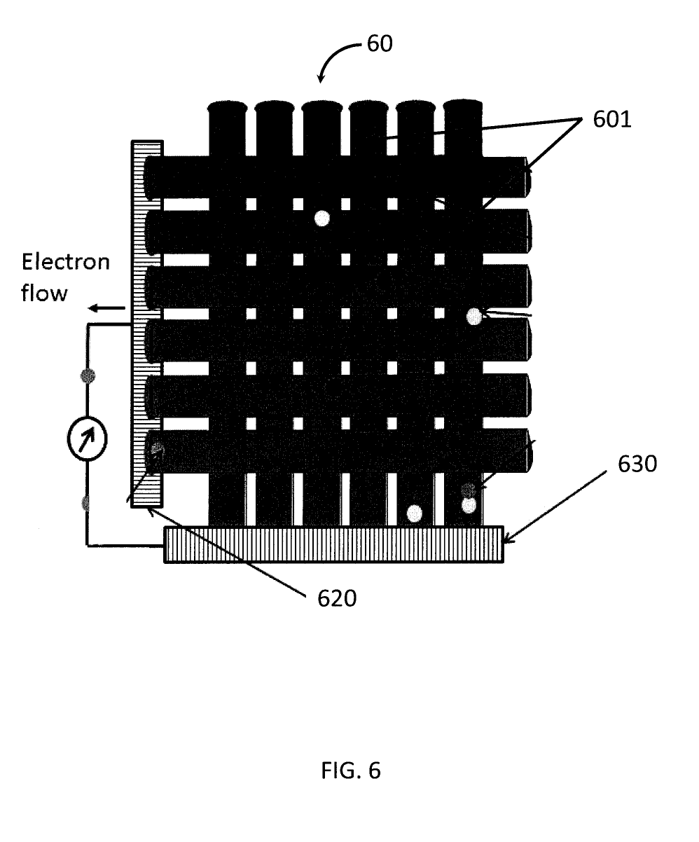

As shown in FIG. 6, the mats 60 of various embodiments may include an anode 630 and a cathode 620, and in certain embodiments, one of the anode 630 and the cathode 620 may be used as a substrate for depositing the nanostrings 601. The anode 630 and cathode 620 may be made from any conductive material including various ceramic and composite materials as well as metals and metal alloys. In particular embodiments, the anode 630 and cathode 620 may be metallic. In some embodiments, the anode 630 and the cathode 620 may be made from the same material, and in other embodiments, the anode 630 and the cathode 620 may be made from different materials. The orientation of the anode 630 and cathode 620 may vary among embodiments. For example, in some embodiments, the anode 630 may be orthogonal to the cathode 620, and in other embodiments, the anode 630 and the cathode 620 may be in a plane parallel to that of the layer of nanostrings 601 and on opposite sides of the layer of nanostrings 601. In certain embodiments, one or both of the anode 630 and the cathode 620 may be transparent or electrically transparent. In particular embodiments, the anode 630 and cathode 620 can be localized on the non-illuminated side of the mat to avoid a potential shading effect on light incident to the mat 60.

As alluded to above, various materials may be used for the anode 630 and the cathode 620. The anode 630 and/or the cathode 620 may be made from metals such as, for example, aluminum, silver, gold, copper, platinum, iron, tungsten, tin, titanium, nickel, and the like and combinations thereof. In some embodiments, alloys such as, for example, carbon steel, tin/lead, tin-copper-silver, bismuth-tin-lead, indium-lead, indium-tin-lead-cadmium, tin-lead-silver, lead-indium-silver, tin-silver, tin-copper, tin-zinc, tin-aluminum, indium-gold, Nitinol, and the like and combination thereof may be used for making the anode 630 and/or the cathode 620. In certain embodiments, the anode 630 and cathode 620 may be composed of an ink prepared from a metal or metal alloys such as those described above and blends of these materials, mixed with certain additives that can promote adhesion. In further embodiments, doped metal oxides such as, for example, indium doped tin oxide, fluorine doped tin oxide, doped zinc oxide, and/or the like, may be used for making the anode 630 and/or the cathode 620 in some embodiments. Other materials that may be used for making the anode 630 and/or the cathode 620 include doped and/or undoped conducting polymers such as, for example, derivatives of polythiophenes, polyaniline, polypyrrole, polyacetylene, combinations thereof, and/or the like.

In particular embodiments, the mat may be patterned. For example, in some embodiments, conductor material may be deposited on a nanostring mat in a pattern in which various portions of the mat are contacted by the conductor material and various other portions of the mat are not. In certain embodiments, the conductor material may be an anode or a cathode or separate conductor materials may be deposited onto the mat as anode and cathodes. In such embodiments, one or both of the conductor materials may be patterned independently patterned on the mat. In further embodiments, patterning may be carried out by controlling deposition of encapsulating material layers onto the nanostrings, controlling transforming of the nanostrings, and combinations thereof. For example, in some embodiments, varying thicknesses of nanostrings encapsulating material layers or recrystallization or coating layers on the nanostrings in one portion of the mat versus other portions of the mats can create a patterned material.

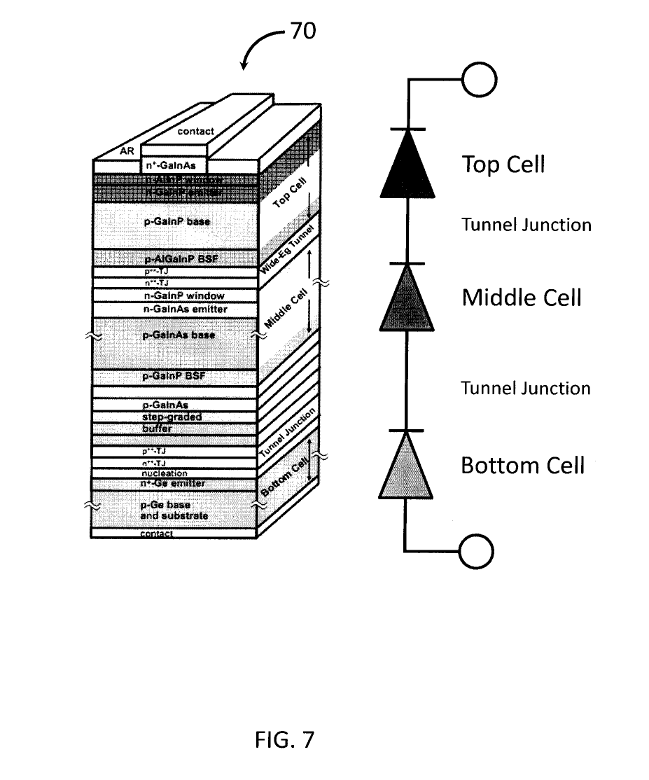

The multi-layered mats described above can be used to produce multi junction cells. FIG. 7 provides a schematic representation of a current multi junction cell having twenty layers of semiconductor material, and is an example of a multi junction photovoltaic cell 70 in which the layers of semiconductor materials absorb energy of different wavelengths. Such devices are, typically, made by depositing layers of semiconductor material in succession using, for example, chemical vapor deposition (CVD). The layers absorb different wavelengths of light and convert the light energy into electrical energy, and the layers are typically arranged to absorb higher energy light first. Therefore, semiconductor materials closer to the substrate and farther from the outer surface that is exposed to radiation are typically lower bandgap materials and semiconductor materials that are closer to the exposed surface of the device are, typically, higher bandgap materials. In use, radiation contacts the exposed surface of the device and is directed first into higher bandgap semiconductor materials, which absorb shorter wavelength (higher energy) portions of the incident radiation and convert this energy into electric energy. Longer wavelength (lower energy) portions of the radiation pass through such higher bandgap materials to lower bandgap materials, where they are absorbed and converted to electric energy. Therefore, the higher energy portions of the incident radiant energy are absorbed and converted to electric energy by the higher bandgap semiconductor materials in the stack without excessive thermalization and loss of energy in the form of heat, while the longer wavelength (lower energy) portions of the radiation are transmitted to one or more subsequent semiconductor materials with smaller bandgaps for further selective absorption and conversion of remaining radiation to electrical energy

Notably, while the device 70 includes twenty individual layers, only three cells that absorb light are formed, a first high-bandgap gallium indium phosphide cell, a second middle bandgap gallium indium arsenide cell, and a third low-bandgap germanium cell. These cells are separated by tunnel junctions. Tunnel junctions form connections between the cells and function as ohmic electrical contacts allowing electrons to pass from one cell to the next, electronically connecting various layers to the substrate. Given the complexity and number of the layers necessary, such devices are difficult to produce.

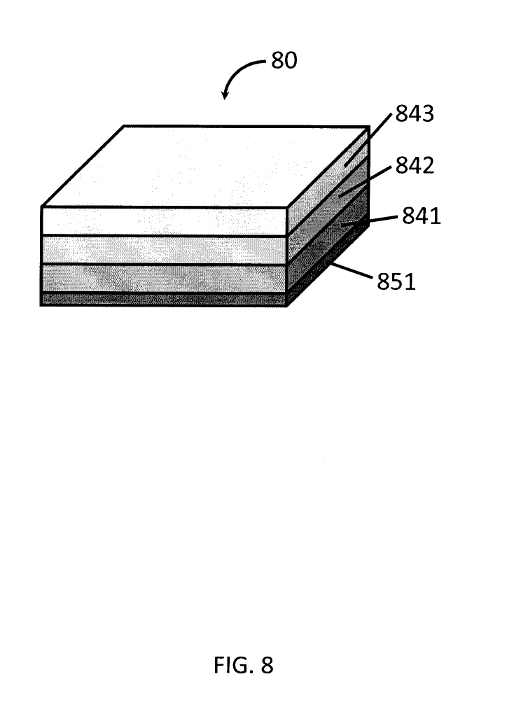

In some embodiments of the invention, two or more layers of nanostrings having different compositions may be disposed one top of one another to create a serially connected device or monolithic multi junction device. FIG. 8 is an example of a two-contact monolithic stack multi junction device 80 including a substrate 851. A first nanostring layer 841 may be composed of nanostrings at least including a first n-type semiconductor material and a first p-type, and a second nanostring layer 842 can be composed of nanostrings including at least a second n-type semiconductor material that is different from the first n-type semiconductor material and a second p-type semiconductor material that is different from the first p-type semiconductor material.

The substrate 851 may be any material described above, including, for example, glass, quartz, silicon, silicon dioxide, metals such as copper, gold, silver, aluminum, tin, and the like and alloys or combinations of metals that are provided as foils, wire-grids, rolls, meshes, webs, wafers, and the like, carbon mattes composed of, for example, carbon black, graphite, graphene, carbon nanotubes, and the like. In some embodiments, the substrate 851 may be transparent and in particular embodiments, the substrate 851 may be conducting. Examples of transparent conducting substrates include, but are not limited to, indium tin oxide, zinc oxide, indium zinc oxide, aluminum zinc oxide, and the like or combinations thereof.

As discussed above, in relation to the single layer mats, the nanostrings for various layers of the multi-layered mats 80 can be composed of a variety of materials and can include layers of any of the conductor and semiconductor materials describe herein. The materials used in each of the nanostring layers 841, 842, 843 can vary, and in certain embodiments, the first nanostring layer 841 may include a low-bandgap semiconductor material such as an inner layer of, for example, indium gallium arsenide or gallium arsenide phosphide, the second nanostring layer 842 may include a middle-bandgap material such as an inner layer of, for example, gallium arsenide, and a third nanostring layer 843 may include a high-bandgap material such as an inner layer of, for example, aluminum gallium arsenide. The cores and/or additional first material layers may include conductive materials, such as those described above, or p-type materials having sufficient holes for accepting electrons from the n-type materials described above. Each nanostring layer 841, 842, 843 may further include an outer layer of an insulating, passivating, and/or reflecting material.

In some embodiments, each nanostring layer 841, 842, 843 may contact adjacent layers directly by depositing each successive layer directly on top of the preceding layer. In other embodiments, an insulating material may be disposed between the successive nanostring layers 841, 842, 843, and in certain embodiments, a tunnel junction material may be disposed between successive nanostring layers 841, 842, 843. In still other embodiments, the tunnel junction material may be incorporated into the nanostrings associated with each layer as the outer layer replacing the insulating material.

Each layer 841, 842, 843 of semiconductor nanostrings may have a thickness of about 0.01 μm to about 10 μm, about 0.1 μm to about 5 μm, or about 0.2 μm to about 1.5 μm, and in certain embodiments the thickness of each nanostring layer 841, 842, 843 may be about 0.5 μm. In some embodiments, the nanostring layers may be substantially transparent, and in certain embodiments, the thickness and/or density of each layer may be modified to increase the transparency of the layer or the overall transparency of the device. For example, the first nanostring layer 841 may have a greater thickness than the second nanostring layer 842 and/or the third nanostring layer 843 to improve the transparency of the upper layers.

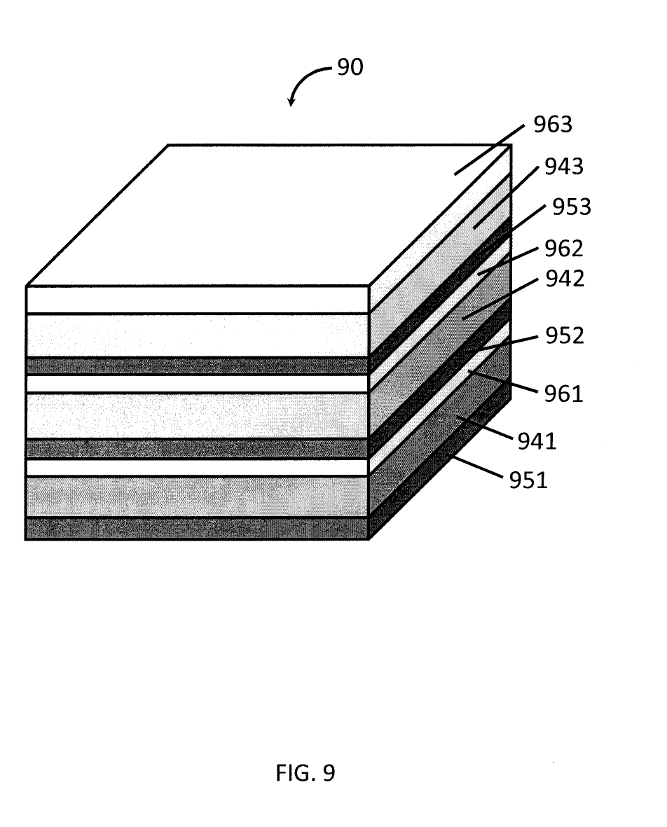

Other embodiments are directed to devices including two or more layers of nanostrings that are mechanically stacked. In such embodiments, each layer of nanostrings may each independently include a substrate, and in certain embodiments, the substrate may be conductive, transparent, flexible, or combinations thereof. FIG. 9 shows an example of a mechanically stacked device including three nanostring layers 941, 942, 943. As illustrated, the first nanostring layer 941 contacts a first substrate 951 and the second nanostring layer 942 contacts the second substrate 952, and so on. Each of these layers may include its own electrical contact allowing electrical energy to be collected from each layer independently. As discussed above in relation to the monolithically stacked devices 80, in various embodiments, nanostring layers 941, 942, 943 in which the nanostrings include a low-bandgap semiconductor material may be lower in the stack away and farther from the surface that is contacted by radiation, and substrate/nanostring layers in which the nanostrings include a high-bandgap semiconductor material may be higher in the stack and closer to the surface that is contacted by radiation.

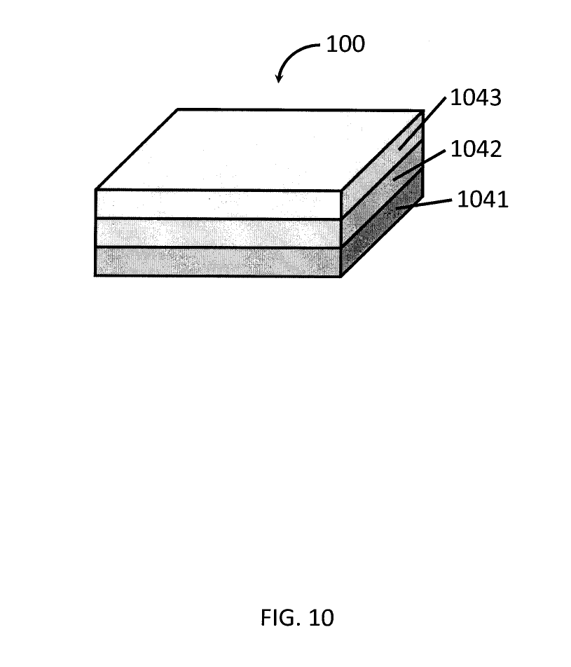

In particular embodiments, each layer of nanostrings may be embedded in a transparent matrix or encapsulating material, allowing each layer to be free standing and eliminating the need for a substrate associated with each layer. FIG. 10 shows an example of such a device 100 including three polymer encapsulated nanostring layers 1041, 1042, 1043. In FIG. 10, each polymer encapsulated nanostring layer 1041, 1042, 1043 directly contacts the adjacent polymer encapsulated layer 1041, 1042, 1043; however, in some embodiments, contact layers or insulating layers may be provided between the polymer encapsulated nanostring layers 1041, 1042, 1043. In such embodiments, each layer or sheet of polymer encapsulated nanostrings 1041, 1042, 1043 can function as an individual single junction device, or, in some embodiments, two separate polymer encapsulated nanostring sheets can be electronically connected to form a tandem device, or three or more polymer encapsulated nanostring sheets 1041, 1042, 1043 can be electronically connected to from a multi junction solar cell. The polymer(s) used to embed the nanostring layers may be any transparent polymer known in the art. For example, in some embodiments, the transparent polymer may be silicone, ethyl vinyl acetate, and the like.

In still other embodiments, polymer encapsulated nanostring sheets 1041, 1042, 1043 can be incorporated into or combined with other devices made by different methods. For example, a polymer encapsulated nanostring sheet can be attached to or otherwise associated with conventional semiconductor wafer materials to create multi junction cells similar to those describe above, where one or more CVD deposited layers are replaced with a polymer encapsulated nanostring sheet layer. In other embodiments, polymer encapsulated nanostring sheets 1041, 1042, 1043 can be incorporated into, for example, conventional crystalline silicon solar cells, thin film solar cells, or the like, to form multi junction solar cells.

In some embodiments, an insulating material may be provided between each nanostring layer 841, 842, 843, 941, 942, 943, 1041, 1042, 1043, and while embodiments include devices in which a tunnel junction material is disposed between nanostring layers 841, 842, 843, 941, 942, 943, 1041, 1042, 1043, in certain embodiments, a tunnel junction material may be omitted from mechanically stacked devices 90, 100. A device having an insulating material between nanostring layers is provided in FIG. 9 and may include a first nanostring layer including a first substrate 951, a first nanostring layer 941, a first insulating material layer 961, and a second nanostring layer in which a second substrate 952 contacts the first insulating layer 961 and separates the first nanostring layer 941 from the second nanostring layer 942 which is disposed on top of the second substrate 952. A second insulating layer 962 may be disposed on top of the second nanostring layer 942 to provide a surface for exposure to radiation or contacting an additional substrate/nanostring insulating layer. Electrical contact may be provided for each successive layer in these devices and may at least be associated with the first and second substrates.

The substrates 951, 952, 953 of such embodiments may be any substrates known in the art and in certain embodiments the substrates may be transparent conductive materials. Such transparent conductive materials include, silica, fumed silica, silicon oxides, certain metals such as copper, gold, silver, aluminum, tin, and the like and alloys or combinations of metals that are provided as foils, wire-grids, rolls, meshes, webs, wafers, and the like, carbon mattes composed of, for example, carbon black, graphite, graphene, carbon nanotubes, and the like, and in some embodiments, indium tin oxide, zinc oxide, indium zinc oxide, aluminum zinc oxide, and the like or combinations thereof

The nanostrings for various layers of the multi-layered mechanically stacked devices 90 can be composed of a variety of materials and can include layers of any of the conductor and semiconductor materials describe above. The materials used in each of the nanostring layers 941, 942, 943 can vary, and in certain embodiments, the first nanostring layer 941 may include a low-bandgap semiconductor material such as an inner layer of, for example, indium gallium arsenide or gallium arsenide phosphide, the second nanostring layer 942 may include a middle-bandgap material such as an inner layer of, for example, gallium arsenide, and a third nanostring layer 943 may include a high-bandgap material such as an inner layer of, for example, aluminum gallium arsenide. The cores and/or additional first material layers may include conductive materials, such as those described above, or p-type materials having sufficient holes for accepting electrons from the n-type materials described above.

Each nanostring layer may further include an outer layer of an insulating material, and in some embodiments the outer layer may be replaced by the insulating layers 961, 962, 963 described above. The insulating materials may vary among embodiments and within the various devices. Examples of transparent insulating materials include, but are not limited to silicone, silicon oxide, silicon nitride, silicon oxynitride, silicon carbide, hafnium oxide, and aluminum oxide, photoresist, benzocyclobutene, cycloalkenes, polyimides, polyamides, polyesters, polyalcohols, polyethylene oxides, polyphenylenes, resins, polyethers, polyketide, and combinations thereof. In certain embodiments, the insulating material may be a transparent polymer such as, for example, plexiglass, polyacetates (e.g., polyethylvinylacetate, ethyl vinyl acetate, polyethylenevinylacetate (EVA), polyvinylacetate), polyacrylates (e.g., polymethylmethacrylate (PMMA)), polycarbonates, olefin (e.g., polypropylene) and cyclic olefin polymers, styrenic polymers (e.g., polystyrene), polyurethanes, polyesters, polyethersulfone, polyimides, fluorinated polymers (e.g., polytetrafluoroethylene ((CH₂CF₂)ₙ) or (CHF)ₙ, polyvinylfluoride), sol-gel polymers (e.g., silica or other oxides), or inorganic-organic hybrid polymer. Such insulating materials may be incorporated into any of the nanostrings, mats, or monolithic devices 80 described above with reference to FIG. 6.

Each of the nanostring layers 941, 942, 943 may have a thickness of about 0.01 μm to about 10 μm, about 0.1 μm to about 5 μm, or about 0.2 μm to about 1.5 μm, and in certain embodiments the thickness of each nanostring layer 941, 942, 943 may be about 0.05 μm. In some embodiments, the nanostring layers 941, 942, 943 may be substantially transparent, and in certain embodiments, the thickness and/or density of each layer may be modified to increase the transparency of the layer or the overall transparency of the device. For example, the first nanostring layer 941 may have a greater thickness than the second nanostring layer 942 and/or the third nanostring layer 943 to improve the transparency of the upper layers. The insulating material may have a thickness of about 10 μm to about 250 μm, about 15 μm to about 200 μm, or about 25 μm to about 100 μm or any value or range within these ranges.

Each nanostring layer of the mechanically stacked devices 90 described above may include an electric contact, conductive leads, or conductive pads in electrical communication with the nanostring layer. The conductive leads or pads allow current to flow through the conductive substrate to external devices that are powered or charged by the device. In some embodiments, the conductive leads or pads may be positioned at the perimeter of the nanostring layer and in other embodiments, the leads or pads may contact the nanostring layer within the stack by being routed between the substrate and the adjoining insulating material or being encapsulated in the insulating material to a contact point on the nanostring layer.

Each nanostring layer of the monolithic devices described above and exemplified by FIG. 8 and each nanostring layer of the mechanically stacked devices described above and exemplified by FIG. 9 and FIG. 10, incorporate the structural elements described above in relation to the nanostrings exemplified by FIG. 5 and mats exemplified by FIG. 4. Therefore, any particular element or limitation described with regard to any particular nanostring or mat can be incorporated into the description or claims describing or claiming monolithic devices and mechanically stacked devices. As such, each particular embodiment described above can be interchangeably incorporated into any other embodiment described in this document.

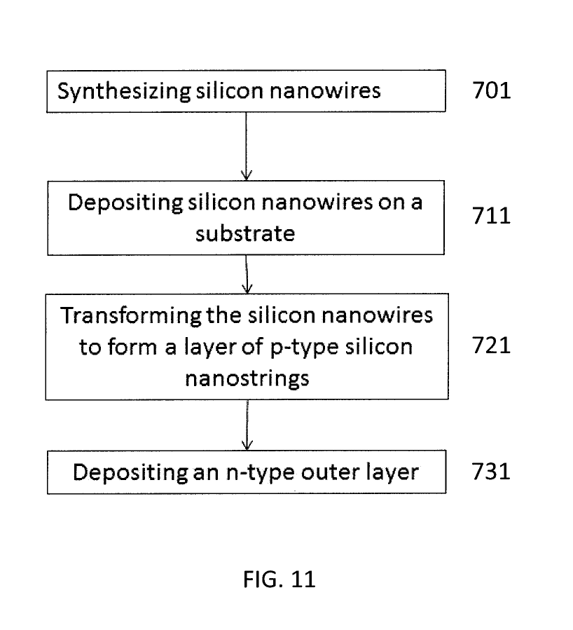

Further embodiments are directed to methods of making semiconductor nanostrings. FIG. 11 is a flow diagram of a method of synthesizing semiconductor nanostrings. In some embodiments, a method for fabricating a semiconductor nanostring may include synthesizing 1101 semiconductor nanostrings, depositing 1111 the nanostrings on a substrate to form a layer of nanostrings, transforming 1121 the deposited nanostrings to form p-type semiconducting nanostrings, and coating 1131 an n-type outer layer on each semiconductor nanostring. In various embodiments, transforming 1121 may include recrystallizing, coating, or otherwise modifying the nanostrings.

In some embodiments, synthesizing 1101 semiconductor nanostrings can be carried out by electrospinning In some embodiments, electrospinning may include combining a liquid silane, a polymer, and a solvent to form a solution, and passing a stream of the solution through an electric field to form fibers. In some embodiments, the liquid silane may be a cyclosilane of the formula SiₙI-1₂ₙ such as, for example, cyclopentasilane, cyclohexasilane 1-silylcyclopentasilane, and/or the like. In some embodiments, the liquid silane may be a linear or branched cyclosilane of the formula SiₙH₂ₙ₊₂, and in particular embodiments, the liquid silane may be Si₆H₁₂. In further embodiments, the liquid silane may further include a polymer, and in some embodiments, the polymer may be, for example, poly(methyl methacrylate), polycarbonate, poly(vinylidene fluoride-co-hexafluoropropylene), and polyvinyl butryal. In some embodiments, the solvent may be, for example, toluene, xylene, cyclooctane, 1,2,4-trichlorobenzene, dichloromethane, or any combination thereof. After the initial spinning, the polymer/silicon wires produced may be converted into silicon nanostrings by, for example, thermal annealing.

In some embodiments, the solution may contain a dopant such as, for example, a metal oxide or an organometallic material. In certain embodiments, the dopant may include particles of metals such as, for example, boron, aluminum, gold, silver, copper, indium, gallium, tin, and the like and combinations thereof, and in other embodiments, the dopant may include particles of semiconducting materials such as, for example, cadmium selenide, cadmium telluride, zinc oxide, gallium arsenide, and/or the like. In various embodiments, the particles may have an average diameter of about 1 nm to about 200 nm. Exemplary average diameters include, but are not limited to, 1 nm, 5 nm, 10 nm, 20 nm, 30 nm, 40 nm, 50 nm, 60 nm, 70 nm, 80 nm, 90 nm, 100 nm, 110 nm, 120 nm, 130 nm, 140 nm, 150 nm, 160 nm, 170 nm, 180 nm, 190 nm, 200 nm, or any value between these values. It is to be understood that specific type and the amount of the dopant in the solution will be determined by one skilled in the art according to the desired doping levels in the semiconductor nanostrings.

In certain embodiments, the nanostrings may include a compound of silicon such as, for example, SiC. In some embodiments, silicon compounds may be introduced during synthesis of the nanostring and can, therefore make up a portion of the precursor solution described above. In other embodiments, such silicon compounds may be formed as a result of carbon contaminates in the precursor solution or trapped in the nanostring during spinning As such, any portion of the nanostring can be composed of a silicon compound. For example, in various embodiments, about 1% or less, up to about 10%, up to about 50%, or up to about 100% of the nanostring may be composed of a silicon compound.

In some embodiments, the semiconductor nanostrings may be deposited on a substrate such as, for example, a metal, a carbon matte, or a rolling mandrel. In some embodiments, the substrate may be, for example, glass, quartz, silicon, silicon dioxide, and/or the like. In some embodiments, the substrate may be in the form of, for example, a foil, a wire-grid, a roll, a mesh, a web, a wafer, and/or the like. Examples of metals that may be used as substrates include, but are not limited to, copper, gold, silver, aluminum, tin, alloys thereof, and/or the like. In some embodiments, the carbon matte may be composed of, for example, carbon black, graphite, graphene, carbon nanotubes, and/or the like. In some embodiments, the rolling mandrel may be made from a conducting tape of, for example, a metal or a carbon matte.

In some embodiments, electrospun nanostrings can be assembled into a collinear layer by applying a secondary potential field while the nanostrings are deposited onto the substrate, and in certain embodiments, the methods may include alternating the position of the secondary potential field allowing layers of strings to be formed orthogonal to each other. By this method a layer structure with a controlled density of strings, and controlled number of inter-string contact points can be formed. Such as collinear nanostrings in each layer can be provided at fixed angles of from about 10° to about 90° or about 15°, about 20°, about 30°, about 45°, about 60°, or about 90°, or any angle encompassed by these exemplary ranges.

In some embodiments, the nanostrings from this process may have a total impurity content of, for example, greater than 200 ppm, greater than 400 ppm, greater than 500 ppm, greater than 1000 ppm or from about 200 ppm to about 1000 ppm or any individual concentration between these exemplary ranges. The nanostrings may have a diameter of less than about 100 nm, less than about 200 nm, less than about 400 nm, or from about 100 nm to about 400 nm or any diameter between these exemplary ranges, and lengths of from about 20 microns to several centimeters, for example, 1 cm, 2 cm, 5 cm, 10 cm, 25 cm, 50 cm, 100 cm, or greater than 500 cm or any length between these exemplary ranges.

In some embodiments, the solution may be expelled from a nozzle. In some embodiments, the electric field may be provided by a high voltage applied between the nozzle and a substrate on which the fibers may be deposited. In some embodiments the distance between the nozzle and the substrate may be, for example, 5 cm, 7.5 cm, 10 cm, 12.5 cm, 15 cm, 17.5 cm, 20 cm, or any value between any two of these values (including the end-points). In some embodiments, the environment between the nozzle and the substrate may be filled with an inert gas such as, for example, nitrogen or argon. In some embodiments, the voltage between the nozzle and the substrate may be, for example, about 5 (kilovolts) kV to about 20 kV. Exemplary voltages used may include 5 kV, 5.5 kV, 6 kV, 7 kV, 8 kV, 9 kV, 10 kV, 10 kV, 11 kV, 12 kV, 13 kV, 14 kV, 15 kV, 16 kV, 17 kV, 18 kV, 19 kV, 20 kV, and/or any value between any two of these values. It is to be understood that one of skill in the art will be able to optimize the conditions for electrospinning using a variety of parameters such as, for example, the particular composition of the solution, the size of the nozzle, the distance between the nozzle and the substrate, the particular environment between the nozzle and the substrate, availability and cost of materials and power supply, and/or the like.

These nanostrings may be further processed or transformed and additional layer of material may be deposited on the outer surface of these core nanostrings. In some embodiments, transforming 1121 the nanostrings may include, for example, thermal processing or photo-processing. In some embodiments, the thermal processing may involve annealing the nanostrings at a temperature of about 150° C. to about 300° C. In some embodiments, the annealing temperatures may be about 300° C. to about 850° C., and in some embodiments, the annealing temperatures may be about 850° C. to about 1414° C. In some embodiments, the thermal processing may be carried out in an inert atmosphere such as a chamber filled with, for example, nitrogen or argon. In some embodiments, the thermal processing may be carried out at low pressures. Examples of pressures that may be used for low pressure annealing include, but are not limited to, 10⁻¹ bar, 10⁻² bar, 10⁻³ bar, 10⁻⁴ bar, 10⁻⁵ bar, 10⁻⁶ bar, and/or any value between any two of these values. In some embodiments, the thermal processing may additionally include rapid thermal processing. It is to be understood that the specific temperature, atmosphere and pressure conditions will depend on factors such as, for example, the exact composition of the pre-cursor, the amount (and type) of dopant, and the type of nanostrings desired, for example, doped nanostrings having a core made of polysilane, amorphous silicon, polysilicon, crystalline silicon, semiconductor materials other than silicon, and the like. One of skill in the art will be able to optimize the various parameters accordingly.

In some embodiments, transforming 1121 the nanostrings may include increasing the diameter of the nanostrings by depositing a semiconductor on the nanostrings using, for example, epitaxy or chemical vapor deposition. Conditions for epitaxy and chemical vapor deposition process may vary among embodiments, and can be optimized by taking into consideration the desired composition and crystallinity of the deposited material, the cost and scalability of the process, and/or the like. In some embodiments, coating 1131 the nanostrings with an n-type outer layer may include depositing a suitable n-type material using a process such as, for example, chemical vapor deposition, plasma enhanced chemical vapor deposition, low-pressure chemical vapor deposition, metalo-organic chemical vapor deposition, the like or combinations thereof. In some embodiments, the n-type material may be epitaxially grown on the nanostrings. In some embodiments, the n-type material may be deposited as a micro-crystalline material on the nanostrings. In some embodiments of n-type material may include silicon doped with, for example, phosphorus, arsenic, antimony, and/or the like.

Methods for depositing additional layers of material on the nanostrings of the invention can include various additional steps. For example, in some embodiments, the surface on an underlying layer may be recrystallized one or more times before the next layer deposited onto the surface of underlying layer. For example, methods of embodiments may include the step of recrystallizing a core before depositing a first outer layer onto the core, recrystallizing a first outer layer before depositing a second outer layer onto the first outer layer, or combinations thereof. Without wishing to be bound by theory, recrystallization may improve the patterning of crystallized layers applied to the recrystallized layers by chemical vapor deposition, or allow for epitaxial growth of subsequent layers.

In some embodiments, the n-type outer layer may be coated during the synthesis of the nanostrings. In some embodiments, an annular nozzle may be used for electrospinning the nanostrings. In such embodiments, an inner annulus of the annular nozzle is fed with a p-type doped precursor solution and an outer annulus of the annular nozzle is fed with an n-type doped precursor solution. Various embodiments of the p-type doped precursor solution are described herein. Dopants that can be used in composition of an n-type doped precursor solution are known in the art and may include, for example, particles of phosphorus, arsenic, antimony, phosphorus oxide, and/or the like. It is to be understood that the parameters for the transforming process for such nanostrings may be different from the parameters used for transforming the p-type doped nanostrings.

In some embodiments, cyclic silanes of the green nanostrings (i.e., unprocessed nanostrings after electrospinning) can be processed, first using photo-polymerization using 266 nm, 355 nm, or 405 nm light to produce solidified polysilane networks. This intermediate step of photo-polymerization solidifies the Si₆H₁₂ so to retain its electrospun shape and reduce mass loss during thermal processing. The nanostrings can then be processed to a μc-Si state via thermal processing.

Some embodiments are directed to methods for manufacturing devices including a monolithic stack 80 of nanostring layers as illustrated in FIG. 8. Such methods may include the step of providing a substrate, electrospinning core nanostrings, depositing the core nanostrings onto the substrate, at least partially coating the core nanostrings with one or more inner layers wherein each inner layer includes a semiconductor material, at least partially coating the core nanostrings coated with the one or more inner layers with an outer layer to produce a first multi-layered nanostrings layer. In some embodiments, such methods may further include coating the first multi-layered nanostrings layer with a tunnel junction material, coating the first multi-layered nanostrings layer with an insulating material, or combinations thereof. The core nanostrings, and one or more inner layers can be composed of any material described above, and in certain embodiments, the one or more inner layers may at least include a low-bandgap semiconductor material.

[000102] In certain embodiments, such methods further include the steps of electrospinning core nanostrings, depositing the core nanostrings onto the first multi-layered nanostrings layer, at least partially coating the core nanostrings with one or more inner layers wherein each inner layer includes a semiconductor material, at least partially coating the core nanostrings coated with the one or more inner layers with an outer layer to produce a second multi-layered nanostrings layer. In some embodiments, such methods may further include coating the second multi-layered nanostrings layer with a tunnel junction material, coating the second multi-layered nanostrings layer with an insulating material, or combinations thereof. The core nanostrings, and one or more inner layers in the second multi-layered nanostring layer can be composed of any material described above, and in certain embodiments, the one or more inner layers may at least include a middle bandgap semiconductor material.

In further embodiments, such methods further include the steps of electrospinning core nanostrings, depositing the core nanostrings onto the second multi-layered nanostrings layer, at least partially coating the core nanostrings with one or more inner layers wherein each inner layer includes a semiconductor material, at least partially coating the core nanostrings coated with the one or more inner layers with an outer layer to produce a third multi-layered nanostrings layer. In some embodiments, such methods may further include coating the third multi-layered nanostrings layer with a tunnel junction material, coating the third multi-layered nanostrings layer with an insulating material, or combinations thereof. The core nanostrings, and one or more inner layers in the third multi-layered nanostring layer can be composed of any material described above, and in certain embodiments, the one or more inner layers may at least include a high-bandgap semiconductor material.

In still other embodiments, additional nanostring layers may be deposited on top of the third nanostring layer, between the first and second nanostring layers, between the second and third nanostring layers, or combinations thereof, using the same steps of electrospinning core nanostrings, depositing the core nanostrings, at least partially coating the core nanostrings with one or more inner layers and outer layers, and, in some embodiments, coating the nanostring layer with a tunnel junction material, an insulating material, or both. The type or semiconductor material used in the additional layers may vary depending on their location, and in certain embodiments, the semiconductor materials may have a higher bandgap than the semiconductor material used in the multi-layered nanostring layer made in the previous step. Such devices including a plurality of multi-layered nanostring layers can include, for example, 3, 4, 5, 6, 7, 8, 9, 10, or up to about 20 nanostring layers.

Various embodiments are directed to methods for making mechanically stacked devices 90 including a plurality of nanostring layers as illustrated in FIG. 9. Such methods may include the steps of providing a first substrate, electrospinning core nanostrings, depositing the nanostrings onto the substrate, at least partially coating the core nanostrings with one or more inner layers and one or more outer layers, wherein each inner layer and outer layer includes a semiconductor material, at least partially coating the core nanostrings coated with the one or more inner layers with an outer layer to produce a first nanostring layer. In some embodiments, such methods may further include depositing an encapsulating material over the multi-layered nanostrings. In other embodiments, the step of at least partially coating the core nanostrings coated with the one or more inner layers with an outer layer may be omitted or replaced by the step of depositing an encapsulating material on the core nanostrings coated with the one or more inner layers. In particular embodiments, the encapsulating material may be deposited at sufficient thickness to produce a substantially planar surface onto which a nanostring layer can be placed. In some embodiments, the substrate may then be removed to produce a nanostring layer having no substrate.

The step of coating the core nanostrings with inner and outer layers and depositing an encapsulating material can be carried out by any method or combination of methods known in the art. For example, in some embodiments, coating and depositing may be carried out by chemical vapor deposition (CVD). In other embodiments, depositing and coating may be carried out using metal-organic chemical vapor deposition (MOCVD), molecular beam epitaxy (MBE), liquid phase epitaxy (LPE), and the like or other semiconductor growth methods and combinations of such methods.

Such methods may further include the steps of providing a second substrate, electrospinning core nanostrings, depositing the nanostrings onto the substrate, at least partially coating the core nanostrings with one or more inner layers wherein each inner layer includes a semiconductor material, at least partially coating the core nanostrings coated with the one or more inner layers with an outer layer to produce a second nanostring layer. In some embodiments, such methods may further include depositing an encapsulating material over the multi-layered nanostrings. In other embodiments, the step of at least partially coating the core nanostrings coated with the one or more inner layers with an outer layer may be omitted or replaced by the step of depositing an encapsulating material on the core nanostrings coated with the one or more inner layers. In some embodiments, the substrate may then be removed to produce a nanostring layer having no substrate. The method may further include the step of contacting the first nanostring layer with the second nanostring layer to produce a mechanically stacked multi junction cell.

In further embodiments, the methods may include additional steps of providing a substrate, electrospinning core nanostrings, depositing the nanostrings onto the substrate, at least partially coating the core nanostrings with one or more inner layers wherein each inner layer includes a semiconductor material, at least partially coating the core nanostrings coated with the one or more inner layers with an outer layer to produce a nanostring layer, and in some embodiments, depositing an encapsulating material over the multi-layered nanostrings. In some embodiments, the substrate may then be removed to produce a nanostring layer having no substrate. These steps can be repeated as necessary to produce all required nanostring layers, and these methods may include the steps of contacting a nanostring layer with another nanostring layer such that the insulating layer of a lower nanostring layer contacts the substrate of an upper nanostring layer.

In some embodiments, such methods may further include the steps of contacting each of the nanostring layers electrical contact, conductive leads, or conductive pads, and in further embodiments, the methods may include the step of contacting an electrical device or battery with wires associated with the electrical contact, conductive leads, or conductive pads. In certain embodiments, contacting may be carried out by providing a partially uncoated first semiconductor material nanostring layer (for example p-type) that can be contacted with a metal. In such embodiments, a portion of the nanostring layer may be coated with a second semiconductor material (for example n-type) leaving an uncoated portion of the nanostring layer. A transparent polymer, encapsulating material, that can be insulating or conducting may be used to embed the nanostrings into a sheet. If insulating, the second semiconductor can be contacted by a second metal while not interfering with the high conduction path between the first semiconducting material and metal touching it. If conductive, the polymer can act as the conductor for the second semiconducting material, touching all the nanostrings. In this case, the conductive transparent polymer could not touch the first semiconducting material or metal contact.

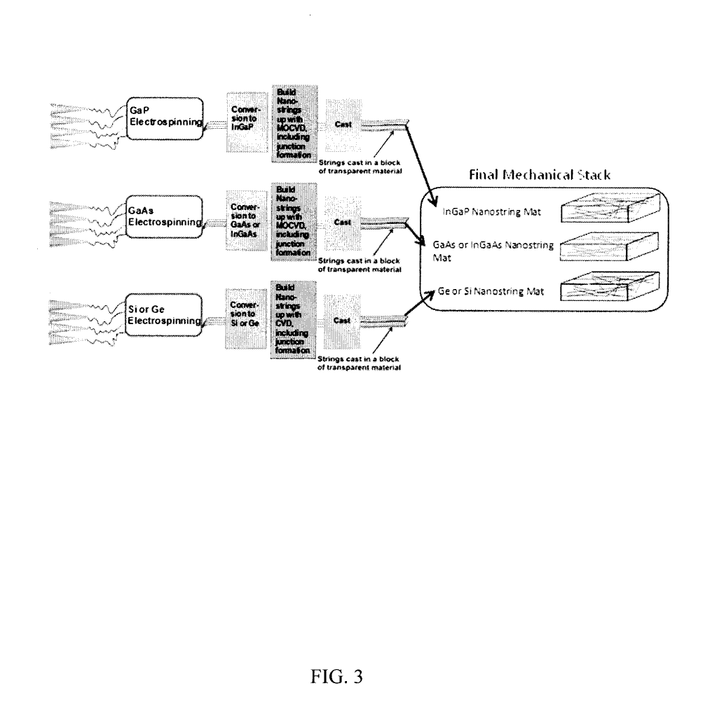

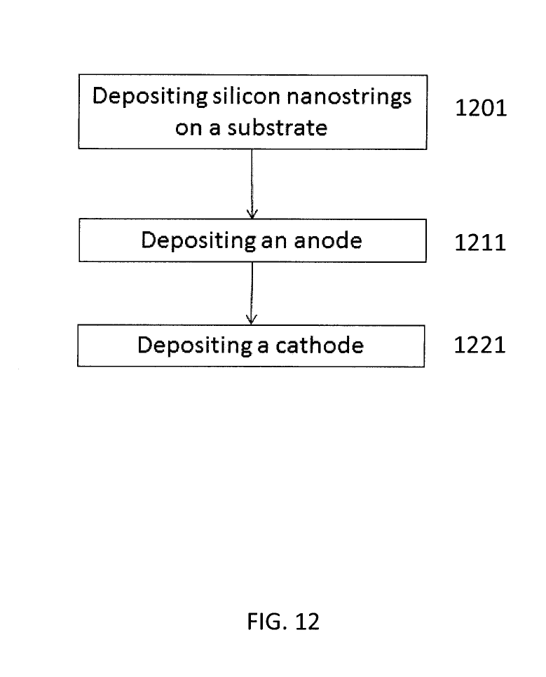

Some embodiments are directed to methods of fabricating a photovoltaic module. FIG. 12 is a flow diagram of an example of a method for fabricating a photovoltaic module according to an embodiment, and FIG. 3 is a schematic showing an example of a method for making a multi junction module. In some embodiments, a method of fabricating a photovoltaic module may include depositing 1201 at least one layer of silicon nanostrings having a p-type core and an n-type shell on a substrate, and depositing 1211 an anode such that the anode is in electrical contact with a p-type portion of the nanostrings, and depositing 1221 a cathode and the cathode is in electrical contact with an n-type portion of the nanostrings.

Various embodiments of nanostrings and methods of depositing the nanostrings are described above and any such method can be used in embodiments. Any of the materials used as the anode and the cathode are described above can be used in embodiments. In some embodiments, depositing 1211 an anode may include etching the nanostrings to expose the p-type core and depositing a suitable anode material on the etched portion of the nanostring so as to make an electrical contact between the anode material and the p-type core.

In certain embodiments, the depositing the anode material may be carried out using techniques such as, for example, sputtering, thermal evaporation, electron-beam vaporization, pulsed laser deposition, and the like and combinations thereof. In some embodiments, methods may include the step of etching the anode material to remove the anode material deposited on n-type outer layer. In particular embodiments, the etching may be preceded by a lithography step to define the portion of the anode material that is to be etched. Examples of techniques that may be used for etching the nanostrings or the anode material include, but are not limited to, wet chemical etching, plasma etching, ion milling, laser ablation, photo-milling, reactive ion etching, and/or the like. In some embodiments, the anode material may be deposited using direct-write techniques such as, for example, dip-pen lithography.

In some embodiments, depositing 1221 the cathode may include depositing a suitable cathode material using techniques such as, for example, sputtering, thermal evaporation, electron-beam vaporization, pulsed laser deposition, and/or the like. In certain embodiments, methods may include the step of etching a portion of the cathode material. Various embodiments for techniques of etching the cathode material are described above.

Various materials that may be used for the anode and/or the cathode are described above. In some embodiments, the anode material and the cathode material may be the same and in some embodiments, the anode material and the cathode material may be different. In certain embodiments, the one or both the anode and the cathode may be transparent. In particular embodiments, one of the anode and the cathode may be used a substrate for depositing the nanostrings.

Various embodiments can include the step of applying a mask to area portion of the mat material prior to growth of one or more outer layers of semiconductor material and or coating layers, allowing growth to occur for a period of time, and removing the mask to expose inner material for contact with the conducting material. In such embodiments, the mask may be composed of masking agents such as, but not limited to, silicon dioxide, silicon nitride, and other high temperature materials. In other embodiments, a mask may be applied before the conducting material, i.e., the anode and/or cathode, is deposited onto the mat. Thus, some methods of embodiments include the step of applying a mask to a mat, depositing a conducting material onto the mat, and removing the mask. In particular embodiments, such method steps may be repeated to provide separate patterned conducting material layers, for separately applying an anode and a cathode material, or various combinations of these.

In some embodiments, a single layer of the semiconductor nanostrings may be used in a photovoltaic module. The single layer may be deposited on any of the substrate materials described herein. In some embodiments, the nanostrings lie along the substrate. In other embodiments, the nanostrings may be aligned parallel to each other, and in still other embodiments, the nanostrings may be aligned at one or more different angles or aligned at random angles. Of course, in certain embodiments, portions of the nanostrings of a material may be disposed along the substrate, parallel to each other, and aligned at one or more different or random angles.

In some embodiments, multiple layers of semiconductor nanostrings may be used in the photovoltaic module. In certain embodiments, the multiple layers may be deposited such that subsequent layers may lie randomly oriented over each other. In other embodiments, the subsequent layers may be aligned orthogonal to each other, and in still other embodiments, the subsequent layers may be aligned at a specific angle forming a patterned material. The number of layers in multiple layered devices may vary among embodiments, and may be limited based on the likelihood of photons not reaching the bottom layers wasting the utility of the bottom layers.

### EXAMPLES

Although the present invention has been described in considerable detail with reference to certain preferred embodiments thereof, other versions are possible. Therefore the spirit and scope of the appended claims should not be limited to the description and the preferred versions contained within this specification. Various aspects of the present invention will be illustrated with reference to the following non-limiting examples. The following examples are for illustrative purposes only and are not to be construed as limiting the invention in any manner.

### Example 1

### Modeling of Efficiency Potential

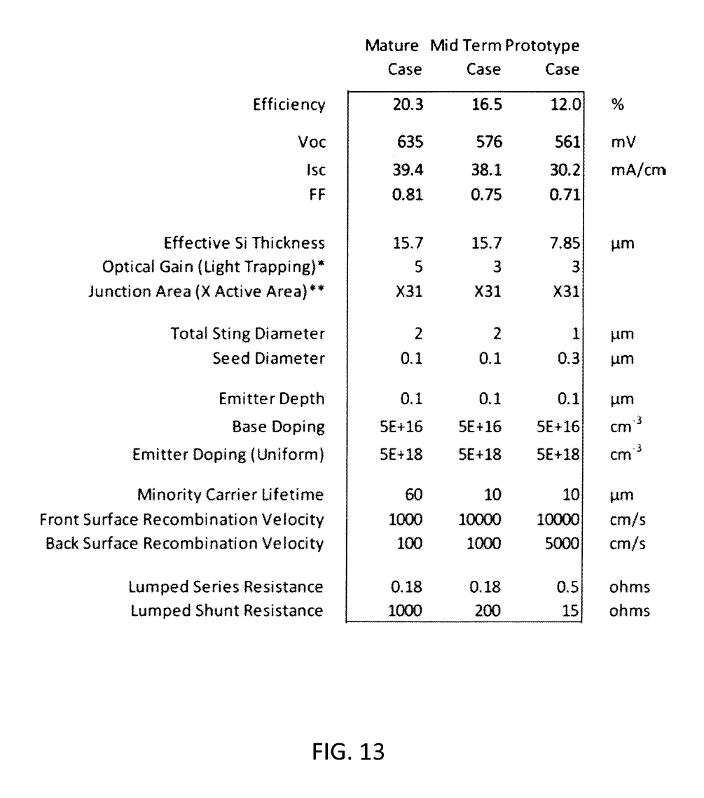

Spectrally weighted absorption of an idealized structure of densely packed fibers is modeled. The model shows that a 10 fiber stack of 2 micron (μm) diameter wires and an internal optical path length equal to 5 times the thickness will absorb 88% of the AM1.5G spectrum. For modeling purposes, all light absorbed in the electrospun seed crystal is considered lost. The results of this model are shown in FIG. 13. FIG. 13 shows minority carrier diffusion lengths as low as 10 μm resulting in good collection efficiency. This is a desirable aspect of the device, and allows the grown crystals a wide range of defects, impurities, and grain boundaries. Small grain polycrystalline silicon, with grain boundaries running columnar from the core of the string, can reach the desired silicon quality modeled.

### Example 2

Unprocessed silicon nanostring mats can be made by electrospinning nanostrings from a single nozzle apparatus. The nanostrings will be long, flexible, and unbroken having uniform diameters of 100 nm-200 nm. Areas of interconnection will exist where the nanostrings intersect with themselves or with other nanostrings.

Raman spectra of nanostrings processed to 800° C. should show the optical phonon transverse mode of a-Si at 485.8 cm⁻¹. The uniform surface morphology will make the fiber suitable as a substrate for CVD deposition of silicon at high temperatures.

A cross-sectional view of electrospun Si-nanostring and an electrospun Si-nanostring having a conformal silicon coating deposited using atmospheric pressure chemical vapor deposition (AP-CVD) should show a distinct and uniform silicon coating completely covering the core silicon nanostring. The recrystallized nanostring material can be thickened by thermal CVD or plasma-enhanced CVD process. Higher order silane gas can be used as a precursor (as opposed to SiH₄) which will allow for higher growth rates and lower temperatures.

### Example 3

### Absorption Measurements on Amorphous Silicon Nanostrings.

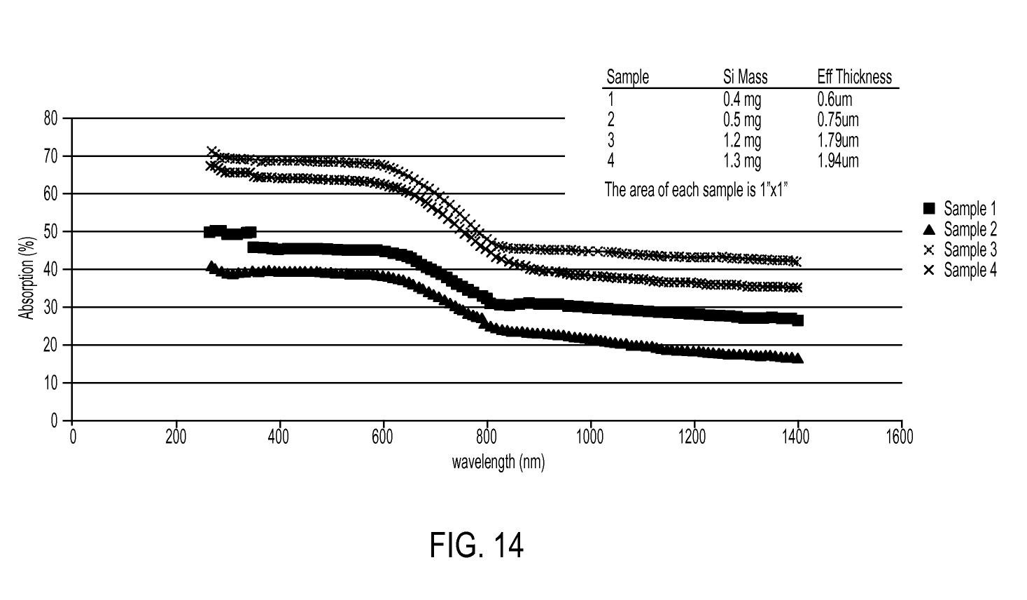

A thin layer of random, amorphous silicon nanostrings is coated on a quartz substrate. FIG. 14 shows the results of absorption measurements on these nanostrings. It is to be noted that the deposition parameters for these nanostrings are not optimized for alignment and/or recrystallization. Better optimization will result in absorption efficiencies higher than 70%.

Various of the above-disclosed and other features and functions, or alternatives thereof, may be combined into many other different systems or applications. Various presently unforeseen or unanticipated alternatives, modifications, variations or improvements therein may be subsequently made by those skilled in the art, each of which is also intended to be encompassed by the disclosed embodiments.

### Example 4

### Design of Multi Junction Nanostring Devices

Two Junction Device: A gallium arsenide on silicon tandem can be made by electrospinning gallium arsenide semiconductor material. A gallium nitrate and PVA sol-gel solution will be created and electrospun in an arsenic-containing atmosphere to produce gallium arsenide nanostrings.

Other Methods for electrospinning gallium arsenide nanostrings that do not require an arsenic-containing atmosphere are also envisioned. These methods will involve adding arsenic-containing compounds such as, for example, arsenic oxide hydrates, arsenic oxides, and arsenic alkoxides to the gallium nitride sol-gel ink solution prior to electrospinning

The electrospun materials can be annealed both via thermal and laser annealing processes. For example, a large-diameter tube furnace capable of annealing at 1000° C. in inert or reducing atmospheres will be used for the thermal annealing tests. For convenience, a carrier such as a quartz slide can be used to transport the nanostrings through this process. After recrystallization the stings can be thickened by deposition of GaAs via MOCVD. First a p layer will be grown, and then an n layer will be grown. The MOCVD growth can act to physically and electrically connect the strings at the points where they are in contact. The process will allow for some areas of the p type material to left uncoated for later electrical contact. The n-type can also be contacted. Finally a surface passivation layer can be added to suppress unwanted carrier recombination at the surfaces, and then an antireflection coating can be added. The working device can then be encapsulated in silicone, with just the electrical contacts exposed. Three discrete layers can be formed, with three discrete semiconductors making up the nanostrings in each layer. The layer closed to the radiation will be Gallium Phosphate, the middle layer will be GaAs, and layer furthest from the radiation will be Germanium.

As an alternative to metal-organic chemical vapor deposition (MOCVD), the nanostring thickening can be carried out with chemical vapor deposition (CVD), molecular beam epitaxy (MBE), liquid phase epitaxy (LPE), or other semiconductor growth methods.

### Example 5

A discrete device formed with GaAs and embedded in silicone, can be added on top of a convention silicon solar cell device. In the example, the radiation will strike the GaAs nanostring device first, and the high energy radiation can be absorbed and an electrical current generated. The lower energy light can be transmitted through the GaAs device and will be absorbed by the silicon solar cell device. The contacts for each device can be handled separately. Many such devices can be wired such that the GaAs top cell devices making up an independent array that will provide power to a solar power generating system and can be operated independently to insure it is operating at the maximum power point. Similarly, the silicon devices will be wired independently to insure they are operating at the maximum power point. Working as part of an overall solar power generating system, the two sets of solar cells will act as independent arrays.

What is claimed is:

1. A nanostring comprising:
at least one core nanostring having a length of greater than 20 μm; and
at least one semiconductor layer covering the at least one core.

2. The nanostring of claim 1, wherein the core nanostring comprises crystalline silicon.

3. The nanostring of claim 2, wherein the crystalline silicon comprises from about 75 wt. % to 100 wt. % of the core nanostring.

4. The nanostring of claim 2, wherein the core nanostring further comprises a dopant material.

5. The nanostring of claim 4, wherein the dopant material is selected from the group consisting of, aluminum, boron, phosphorous, arsenic, gallium, antimony, indium, and combinations thereof.

6. The nanostring of claim 4, wherein the core nanostring further comprises from about 0.001 wt. % to about 25 wt. % dopant material.

7. The nanostring of claim 4, wherein the dopant material enhances the electrical conductivity of the core nanostring.

8. The nanostring of claim 1, wherein the core nanostring comprises a semiconductor material.

9. The nanostring of claim 8, wherein the semiconductor material is selected from the group consisting of silicon, carbon, germanium, aluminum nitride, gallium nitride, indium gallium arsenide, aluminum gallium arsenide, cadmium selenide, cadmium sulfide, cadmium telluride, zinc oxide, zinc selenide, zinc sulfide, zinc telluride, cadmium zinc telluride, mercury cadmium telluride, mercury zinc telluride, mercury zinc selenide, aluminum antimonide, aluminum arsenide, aluminum nitride, aluminum phosphide, boron nitride, boron phosphide, boron arsenide, gallium antimonide, gallium arsenide, gallium nitride, gallium phosphide, indium antimonide, indium arsenide, indium nitride, indium phosphide, aluminum gallium arsenide, indium gallium arsenide, indium gallium phosphide, aluminum indium arsenide, aluminum indium antimonide, gallium arsenide nitride, gallium arsenide phosphide, aluminum gallium nitride, aluminum gallium phosphide, indium gallium nitride, indium arsenide antimonide, indium gallium antimonide, aluminum gallium indium phosphide, aluminum gallium arsenide phosphide, indium gallium arsenide phosphide, aluminum indium arsenide phosphide, aluminum gallium arsenide nitride, indium gallium arsenide nitride, indium aluminum arsenide nitride, gallium arsenide antimonide nitride, gallium indium nitride arsenide antimonide, gallium indium arsenide antimonide phosphide, and combinations thereof

10. The nanostring of claim 8, wherein the core nanostring further comprises from about 75 wt. % to about 100 wt. % semiconductor material.

11. The nanostring of claim 8, wherein the core nanostring further comprises a dopant material.

12. The nanostring of claim 8, wherein the dopant material is selected from the group consisting of, copper, aluminum, gold, boron, phosphorous, arsenic, indium, arsenic, gallium, boron, oxygen, and combinations thereof.

13. The nanostring of claim 8, wherein the core nanostring further comprises from about 0.001 wt. % to about 25 wt. % dopant material.

14. The nanostring of claim 8, wherein the dopant material enhances the electrical conductivity of the of the core nanostring.

15. The nanostring of claim 1, wherein the core nanostring has a length of up to about 10 meters.

16. The nanostring of claim 1, wherein the semiconductor layer comprises a semiconductor material selected from the group consisting of silicon, carbon, germanium, aluminum nitride, gallium nitride, indium gallium arsenide, aluminum gallium arsenide, cadmium selenide, cadmium sulfide, cadmium telluride, zinc oxide, zinc selenide, zinc sulfide, zinc telluride, cadmium zinc telluride, mercury cadmium telluride, mercury zinc telluride, mercury zinc selenide, aluminum antimonide, aluminum arsenide, aluminum nitride, aluminum phosphide, boron nitride, boron phosphide, boron arsenide, gallium antimonide, gallium arsenide, gallium nitride, gallium phosphide, indium antimonide, indium arsenide, indium nitride, indium phosphide, aluminum gallium arsenide, indium gallium arsenide, indium gallium phosphide, aluminum indium arsenide, aluminum indium antimonide, gallium arsenide nitride, gallium arsenide phosphide, aluminum gallium nitride, aluminum gallium phosphide, indium gallium nitride, indium arsenide antimonide, indium gallium antimonide, aluminum gallium indium phosphide, aluminum gallium arsenide phosphide, indium gallium arsenide phosphide, aluminum indium arsenide phosphide, aluminum gallium arsenide nitride, indium gallium arsenide nitride, indium aluminum arsenide nitride, gallium arsenide antimonide nitride, gallium indium nitride arsenide antimonide, gallium indium arsenide antimonide phosphide, and combinations thereof.

17. The nanostring of claim 16, wherein the semiconductor material is doped.

18. The nanostring of claim 1, wherein the semiconductor layer completely covers the core nanostring.

19. The nanostring of claim 1, wherein the semiconductor layer partially covers the core nanostring.

20. The nanostring of claim 1, wherein the nanostring core comprises an n-type semiconductor material and the semiconductor layer comprises a p-type semiconductor layer.

21. The nanostring of claim 1, wherein the semiconductor layer comprises a first inner layer and a second inner layer.

22. The nanostring of claim 21, wherein the first inner layer comprises an n-type semiconductor material and the second inner layer comprises a p-type semiconductor material.

23. The nanostring of claim 1, further comprising an outer layer one or more insulating, passivating, or anti-reflecting layer.

24. The nanostring of claim 1, wherein the nanostring has a diameter of about 5 nm to about 2500 nm.

25. A mat comprising:
an encapsulant material; and
at least one nanostring encapsulated within the encapsulant material, the nanostring having:
at least one core nanostring having a length of greater than 20 μm; and
at least one semiconductor layer covering the at least one core.

26. The mat of claim 25, further comprising a substrate selected from the group consisting of glass, quartz, silicon, silicon dioxide, carbon black, graphite, graphene, carbon nanotubes, metals, copper, gold, silver, aluminum, tin, alloys thereof, and combinations thereof.

27. The mat of claim 25, further comprising an anode and a cathode.

28. The mat of claim 25, wherein the at least one nanostring comprises a plurality of interconnected nanostrings.

29. The mat of claim 28, wherein the nanostrings are patterned.

30. The mat of claim 28, wherein the nanostrings are randomly arranged.

31. The mat of claim 25, wherein the at least one nanostring comprises a plurality of collinearly arranged nanostrings.

32. A multi junction device comprising at least one nanostring layers each nanostring of the at least one nanostring layers having:
at least one core nanostring having a length of greater than 20 μm; and
at least one semiconductor layer covering the at least one core.

33. The multi junction device of claim 32, wherein the device is a photovoltaic cell.

34. The multi junction device of claim 32, wherein the multi junction device further comprises a photovoltaic cell.

35. A method for making a nanostring comprising:
electrospinning a core nanostring; and
depositing one or more layers of a semiconductor material onto the core nanostring.

36. The method of claim 35, wherein electrospinning results in a plurality of interconnected nanostrings.

37. The method of claim 35, further comprising encapsulating the nanostring in an encapsulant material.
